(19) United States
(12) Patent Application Publication
(10) Pub. No.: US 2025/0109685 A1
(43) Pub. Date: Apr. 3, 2025

(54) ADAPTIVE MONITORING FOR MANAGING CARBON STORAGE SITES

(71) Applicant: Schlumberger Technology Corporation, Sugar Land, TX (US)

(72) Inventors: Michael William Branston, Kuala Lumpur (MY); Ran Bachrach, Houston, TX (US)

(21) Appl. No.: 18/904,820

(22) Filed: Oct. 2, 2024

Related U.S. Application Data
(60) Provisional application No. 63/587,320, filed on Oct. 2, 2023.

(51) Int. Cl. E21B 49/00; E21B 41/00; G06F 30/28

(52) U.S. Cl. CPC E21B 49/00; E21B 41/0064; G06F 30/28; E21B 2200/20

(57) ABSTRACT

A method for adaptively monitoring a subsurface fluid storage facility. The method may include parameterizing a gas storage model using a computation engine and executing the gas storage model in one or more simulators following which analysis operations may be executed on the modeling results to generate one or more reports and/or automatically or semi-automatically configure equipment associated with gas storage operations at a given resource site. The results from these tests may be fed into one or more analysis engines that condenses the vast simulation results into actionable insights and/or configuration settings, and/or safety data that may be used to optimize the configuration and/or operation of gas storage equipment at a given resource site. The method may pinpoint precise monitoring techniques to deploy at each stage comprised in the gas storage campaign thereby mitigating against gas storage project risks and operational costs.

### PRIORITY APPLICATION

This application claims priority to, and the benefit of, the earlier filing date of U.S. Provisional Patent Application No. 63/587,320 filed on Oct. 2, 2023, titled “ADAPTIVE MONITORING FOR MANAGING CARBON STORAGE SITES”, the contents of all of which are incorporated herein by reference.

### BACKGROUND

Safe subsurface storage of fluids such as hydrogen, methane, and carbon dioxide, for example, is a major challenge facing the energy industry. In particular, subsurface fluid storage has uncertainties that place both development (e.g., financial feasibility) and environmental safety constraints on fluid storage projects thereby negatively impacting project execution and completion timelines for fluid storage. There is therefore a need to develop monitoring mechanisms that monitor or otherwise track fluid storage structures to effectively manage the aforementioned uncertainties, comply with fluid storage requirements from regulatory bodies, and also accurately report carbon storage parameters to stakeholders including said regulatory bodies.

Moreover, conformance requirements for fluid storage systems may be based on time-lapse (4D) image data. This can be acquired using streamers or less commonly seabed nodes. The costs associated with this approach are not only very high but also include significant redundancies with regard to the monitoring fluid plume migration (e.g., CO2 plume migration) activity that relies on developing the 4D image for interpretation.

### SUMMARY

The disclosed technology, according to some embodiments minimizes uncertainties associated with development and safety constraints for fluid storage operations, including but not limited to storage of methane, hydrogen and carbon dioxide. For example, actively preparing for high-risk scenarios associated with fluid storage operations may be accomplished via the design and implementation of effective monitoring campaigns. This ensures efficient fluid containment as fluid leakage events can jeopardize project viability and license acquisition to operate workflows and mechanisms for fluid storage. Moreover, conforming field measurements with well-designed and implemented fluid storage monitoring campaigns can ensure optimal reservoir production operations that enable quantifying and improving fluid storage models with associated predictability data.

According to some embodiments, monitoring of a fluid storage site must continue even after injection operations end (e.g., fluid injection operations) which significantly increases operational bottlenecks (e.g., costs) compared with other hydrocarbon exploratory activities. Additionally, when, for example, an injection operation into a storage complex at a resource site ends, the subsurface model generated (e.g., fluid storage model) for the storage complex needs to have a high level of predictability to support the long-term responsibility for monitoring the stored fluid within the storage complex. The disclosed technology innovatively supports the design of fluid capture and storage monitoring campaigns by quantifying site-specific uncertainties across multiple scenarios and determining or predicting monitoring methods that detect specific risk events. Additionally, the workflows discussed may be automatic, semi-automatic, or a combination thereof and may be based on feedback from real-time or near real-time sensor measurements and/or from historic sensor measurements at the fluid storage site in order to improve the predictability of the fluid storage model, enhance storage site integrity in the long term, and iteratively optimize fluid storage and monitoring campaigns at the fluid storage site.

According to certain embodiments, the method of the current invention includes receiving a first data set that is associated with a fluid storage site. The first data set may include geo-physics data that is associated with the fluid storage site and risk profile data and may be received either from at least one sensor disposed within the fluid storage site, or from an offsite database communicated to the fluid storage site. According to certain embodiments, the method may also include generating a subsurface model for the fluid storage site based on the first data set. The subsurface model may include a plurality of parameters. According to certain embodiments, the plurality of parameters of the subsurface model may include at least one parameter that is based on the geo-physics data associated with the fluid storage site. In certain embodiments, the method may include executing a plurality of simulations using the subsurface model that is based on the fluid data associated with storing fluid in the fluid storage site. The plurality of simulations may be executed across a corresponding plurality of simulators in parallel for a plurality of different predefined time periods. According to certain embodiments, the method may also include generating predicted fluid distribution data based on the executed simulation. The fluid distribution data may include fluid pressure data, CO₂ saturation data, spatial fluid data, or temporal fluid data. According to certain embodiments, the method may also include receiving a second data set that is associated with the fluid storage site. The second data set may be optimized based on the predicted fluid distribution data. According to certain embodiments, the method may include determining that the second data set exceeds a risk threshold. The risk threshold may be based on the received risk profile data. According to certain embodiments, the method may also include adapting at least one of the parameters of the subsurface model and re-executing the at least one simulation to provide updated predicted fluid distribution data in response to the second data set exceeding the risk threshold and then performing an action that may be based in response to re-executing the at least one simulation. Performing an action may include generating quality assurance data to optimize fluid storage operations at the resource site based on the fluid distribution data or generating a gas detection map illustrating gas distribution data associated with the fluid storage site. According to certain embodiments, performing an action may also include configuring a plurality of sensors disposed within the subsurface fluid storage facility or indicating fluid irregularities based on the distribution data. According to certain embodiments, indicating fluid irregularities based on the distribution data may include updating flow simulation parameters comprised in the plurality of parameters of the subsurface model, or developing an optimal survey design and modeling workflow for the subsurface fluid storage facility.

### BRIEF DESCRIPTION OF THE DRAWINGS

The disclosure is illustrated by way of example, and not by way of limitation in the figures of the accompanying drawings in which like reference numerals are used to refer to similar elements. It is emphasized that various features may not be drawn to scale and the dimensions of various features may be arbitrarily increased or reduced for clarity of discussion.

FIG. 1A shows a schematic depiction of the steps of a carbon capture and storage (CCS) project lifecycle and impacts of using seismic data during the decision process within each stage of the CCS project lifecycle, according to an embodiment.

FIG. 1B shows a characterization and assessment overview of the potential carbon capture storage complex and surrounding area, according to an embodiment.

FIG. 1C provides a summary of monitoring techniques, summarised under monitoring objectives, according to an embodiment.

FIG. 1D shows an exemplary high-level workflow associated with building monitoring scenarios for fluid storage and containment operations at a resource site, according to an embodiment.

FIG. 2 shows a cross-sectional view of a resource site for which the process of FIG. 1D may be executed, according to an embodiment.

FIG. 3 shows a networked system illustrating a communicative coupling of devices or systems associated with the resource site of FIG. 2, according to an embodiment.

FIG. 4 shows an exemplary comparison of analysis data used to direct the choice of metrics needed for optimally detecting fluid storage events at a resource site, according to an embodiment.

FIG. 5A shows an exemplary impact of CO₂ injection in terms of pore pressure and gas saturation on elastic properties including velocity, pressure, shear impedance changes, time shifts, and potential anisotropic parameters, according to an embodiment.

FIG. 5B shows the expected seismic response associated with a change in subsurface properties, according to an embodiment.

FIG. 6 shows a detailed workflow for optimizing fluid storage (GS) operations at a resource site, according to an embodiment.

FIG. 7 shows an exemplary flowchart showing a departure from discrete acquisition of data, according to an embodiment.

FIG. 8 shows a workflow for implementing the disclosed adaptive monitoring regime, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

The disclosed systems and methods may be accomplished using interconnected devices and systems that obtain a plurality of data associated with various parameters of interest at a resource site. The workflows/flowcharts described in this disclosure, according to some embodiments, implicate a new processing approach (e.g., hardware, special purpose processors, and specially programmed general-purpose processors) because such analyses are too complex and cannot be done by a person in the time available or at all. Thus, the described systems and methods are directed to tangible implementations or solutions to specific technological problems in developing natural resources such as oil, gas, water well industries, and other mineral exploration operations. More specifically, the systems and methods presently disclosed may be applicable to operations associated with fluid storage at a resource site (e.g., oil field, saline aquifers, etc.).

Attention is now directed to methods, techniques, infrastructure, and workflows for operations that may be carried out at a resource site. Some operations in the processing procedures, methods, techniques, and workflows disclosed herein may be combined while the order of some operations may be changed. Some embodiments include an iterative refinement of one or more data associated with the resource site via feedback loops executed by one or more computing device processors and/or through other control devices/mechanisms that make determinations regarding whether a given action, template, or resource data, etc., is sufficiently accurate.

According to some embodiments of this disclosure, a relevant consideration involved in designing and implementing a fluid capture and storage campaign is the likelihood that method A associated with the fluid capture and storage campaign will detect event B within a range of subsurface uncertainties. Monitoring techniques (e.g., use of sensors to capture real-time and/or near-real time data and/or historic sensor data) for detecting important site-specific risks in the subsurface domain may be optimized for longevity as well as maintaining low operational costs. For the fluid capture and storage operations disclosed herein for designing and implementing fluid storage campaigns, a plurality of different monitoring configurations may be compared against site-specific conditions captured by sensors in real-time or near-real-time or site-specific conditions historically captured by sensors. For example, up to 45 different monitoring configurations may be compared against site-specific conditions according to some embodiments. Two distinct monitoring goals (e.g., containment and conformance) may increase the complexity of the monitoring systems. When the monitoring objective is to confirm conformance to an existing subsurface model, a positive outcome from this may include confirming the accuracy of the generated fluid or gas storage (GS) models using acquired data from the monitoring systems. If the acquired data confirms that the GS model is inaccurate or for example, has a substantially high degree of uncertainty, then additional data may need to be acquired to verify and reduce the uncertainty in the GS model. Given, for example, a monitoring timeframe of about 20 to 50+ years, the process of confirming that the GS model is accurate lends itself to automation or semi-automation operations (e.g., simulations) as the case may require. In other embodiments, at least one aspect of the disclosed techniques involves manually configuring or initiating modeling operations associated with the GS model. For example, the process of ascribing quantitative parameters to a GS model may be a manual process initiated by a user. Initiating tests or simulations using a configured or parameterized GS model, for example, may involve a user activating one or more visual indicators (e.g., test/simulation icon) on a graphical user interface device.

Interest in carbon capture and storage (CCS) has grown significantly in recent years. In particular, support of the societal goal of meeting a net zero carbon emission target has refocussed attention on carbon capture and storage (CCS). In the International Energy Agency (IEA) Sustainable Development Scenario in which global fluid (e.g., CO2) emissions from the energy sector are expected to fall to zero on a net basis by 2070, CCS accounts for nearly 15% of the cumulative reduction in emissions as of 2021. For example, it is estimated by the IEA that between 5700 mega-tonne (Mt) of carbon dioxide (CO2) need to be sequestrated or stored by 2025 to achieve the net zero goal.

This is a significant challenge because of the rapid increase in scale of both carbon capture process and the storage of said carbon. The Global CCS Institute describes this as a rapid scale up. In 2022, 61 new CCS facilities were announced, resulting in 196 CCS projects in development as of September 2022. This is a 44% year-on-year increase in capture capacity, but, importantly, the projects in development will still only store 244 Mt per year of fluid (e.g., CO2) according to the Global CCS Institute in 2022. For example, the IEA indicates that CO2 capture plants take between three and five years to build, while the assessment and development process for CO2 storage can take much longer times. Thus, the surmountable task ahead of the energy transition industry includes that of scaling up CCS or fluid storage operations.

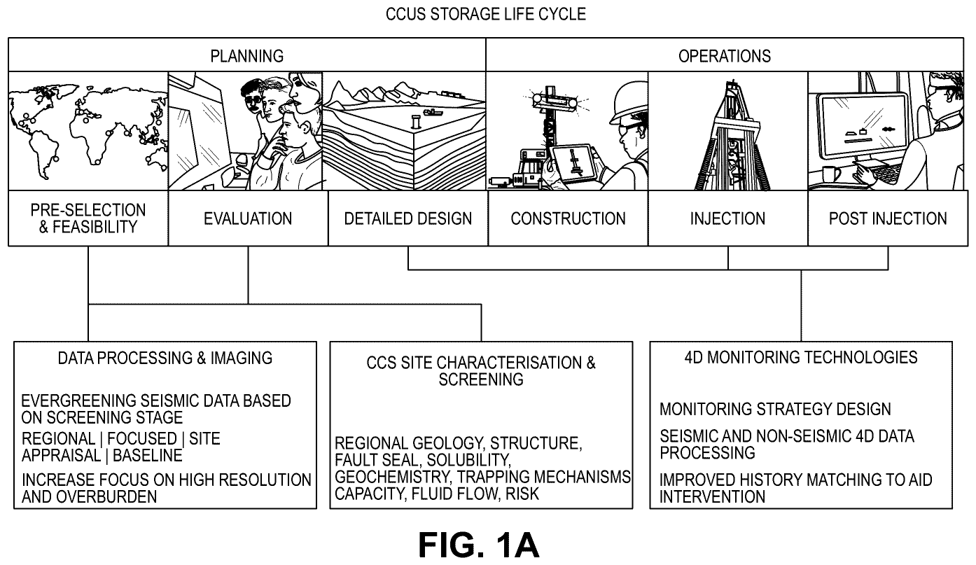

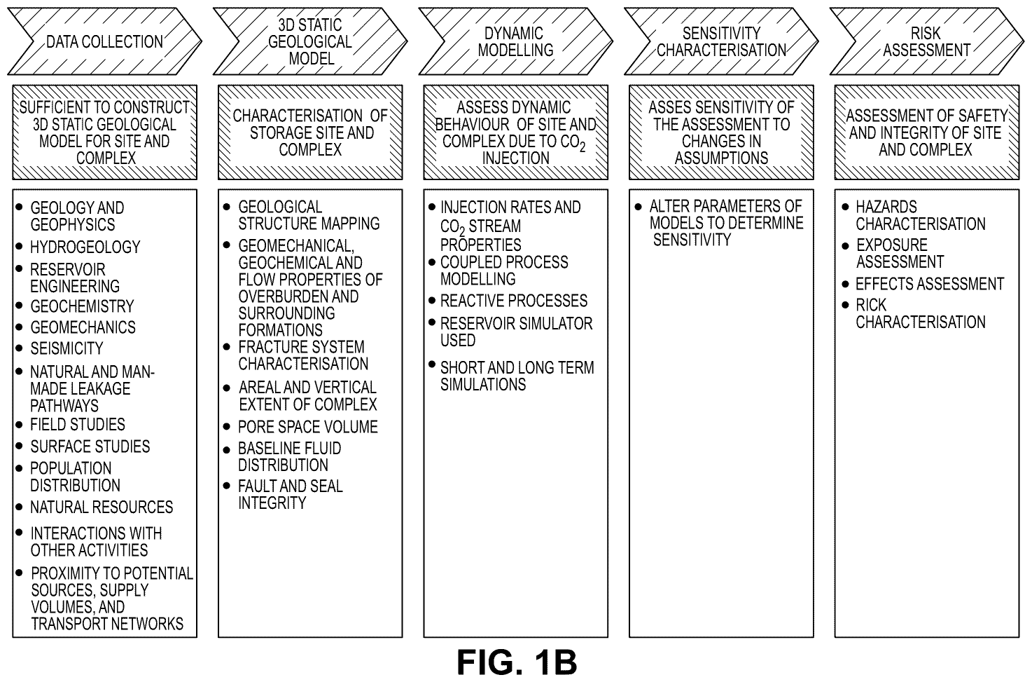

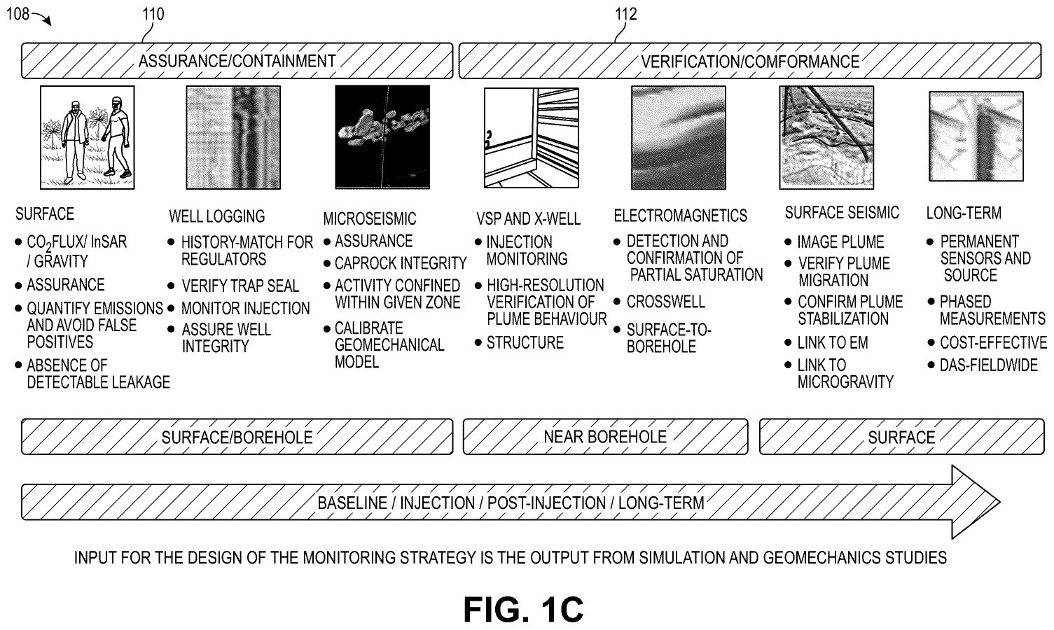

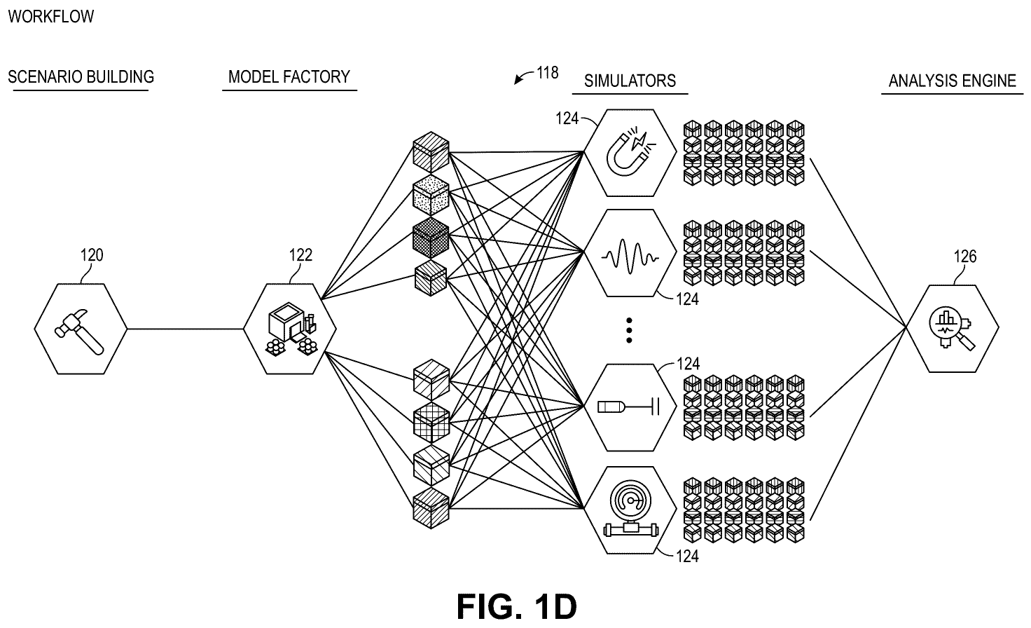

This task may be better understood by reviewing the various phases of the CCS project lifecycle as depicted in FIG. 1A. In particular, FIG. 1A shows a schematic depiction of the steps of the CCS project lifecycle and impacts of using seismic data during the decision process within each stage of the CCS project lifecycle. The CCS project lifecycle can include a multifaceted and complex process requiring significant investment and technical expertise at each of the key steps depicted in FIG. 1A. According to certain embodiments, the CCS project lifecycle includes a planning phase and an operations phase, the planning phase itself including pre-selection and feasibility analysis, evaluation, and producing detailed designs of the CCS site, while the operations phase in turn may include the construction of the CCS site, injection of the captured carbon, and post injection monitoring of the carbon storage.

This disclosure, according to one embodiment, leverages seismic data (e.g., seismic data acquired at the surface) for CCS or fluid storage operations. The development of carbon capture facilities may be based on largest capital expenditure (CAPEX) within the CCS lifecycle process. However, a significant proportion of risk lies within the carbon storage (CS) process itself. CCS lifecycle project decisions may be underpinned by the subsurface screening and characterisation work undertaken ahead of the final CCS development operations based in part on the accuracy of predicted injectivity rates associated with the fluid to be stored as well as capacity of the storage volume required to store the fluid, and operational expenditure (OPEX) associated with monitoring measurement and verification (MMV) strategies stipulated by a regulatory framework. Each of these stages rely heavily on geophysics and in particular seismic data. The balance of cost control and technical excellence is a task with which all within the seismic industry are familiar. However, these aspects are within the monitoring domain, and in particular the post injection and long-term monitoring stages of CCS project—a space in the industry which has the greatest opportunity to innovate and evolve. Geophysics including the acquisition and analysis of seismic data has played a significant role in the exploration of hydrocarbon and mineral resources. For example, seismic data may be used as an exploration tool to provide information on (amongst other things) migration pathways, trapping mechanisms and accurate structural information in the subsurface. According to one embodiment, seismic data may be used to execute screening operations associated with carbon or fluid storage.

In the early stages of understanding gross storage volumes, available data may be used to help with reconnaissance at a regional or basin scale. The challenges of these data sets are numerous, including but not limited to irregular coverage, limited bandwidth, residual noise and multiple energy, inaccurate imaging, and variable illumination. However, the use of legacy data, combined with fast, targeted reprocessing may be used to meet the aspects of the objective of assessing storage potential at a regional scale. In the case of data rich basins, once an area has been identified as a potential storage site, available 2D and/or 3D seismic data are collected (e.g. from national data repositories, multi-client libraries and third-party data libraries) and reprocessed to provide a contiguous post-stack merge with signal enhancement that provide consistent phase as well as amplitude and seismic characteristics to enable structural interpretation across the area. In the site appraisal stage, the area of interest may be reduced to allow for more costly processing sequencies to be applied to the data to improve upon the above-mentioned data quality issues of the vintage data.

The acquisition of new seismic data may depend on a number of factors. In the data rich basin scenario, the new seismic data is linked to uncertainties within the structural interpretation and storage risk identification process and to the chosen MMV strategy as well as the suitability of legacy data sets to provide an adequate seismic baseline reference including the proximity data associated with areas having existing or planned third-party activity, such as dual land use considerations like wind farms. Within the principal projects being executed in Northern Europe, for example, a preference to acquire new, purpose designed seismic data ahead of injection is growing. This data has the dual use of characterizing the fluid storage volume and overburden and a more suitable seismic baseline data set to match the geometry and acquisition parameters that will be deployed during the MMV program.

Furthermore, in the case where the proximity to the emitter is critical to the siting of the storage unit, or in basins that are not rich in legacy 2D and 3D seismic data, the acquisition of purposed designed seismic data is required early in the site screening and feasibility process. This data, according to some implementations, is designed and acquired with its role in the future MMV plan fully considered.

The process of geological play-based screening, using available seismic and well data, is described in the first two columns of FIG. 1B. Specifically, FIG. 1B shows a characterization and assessment overview of the potential storage complex and surrounding area, based on Annex I of CCS-Directive (European Communities, 2011). It is appreciated that the processes of container focused seismic interpretation, geomechanical modelling of the storage site, petrophysical assessment of the storage site, and CO₂ storage capacity estimations may be combined to provide a geological site summary and ranking. This may be further leveraged together with other non-geological criteria, for example the proximity to an emitter or source of CO₂, presence and condition of existing wells in the area and perhaps most importantly, the acceptance of CS operations. This is a complex ranking operation that may require tools that assist in this dynamic process, collect information on capacity and containment including injectivity data (e.g., seal assessment, layer quality assessment, injection pressure), distance to pipeline data, number of nearby wells data, and project cost benchmarking.

The disclosed subject-matter automates the design process for fluid or gas storage (GS) operations at a resource site by directly simulating multiple geological scenarios and monitoring techniques (e.g., seismic, electromagnetic, gravity) thereby allowing users to provide high-level objectives with the computationally intensive low-level details being automated and executed via computational tests or simulations. According to some embodiments, a storage complex or site may be modeled or otherwise digitized in a modeling package using a graphical interface tool such as Petrel™ with relevant information associated with the storage site being available for parameterization to conform to relevant monitoring objectives. The resulting interactive report generated from said modeling may provide stakeholders with an understanding of GS storage considerations at the storage site together with the option to drill-down into specific simulation and/or testing scenarios. By designing open simulator interfaces that can aggregate and or configure GS models for a given resource site, cross-domain factors across multiple domains associated with a given resource site may be factored in the GS campaigns for a given resource site. The cross-domain factors may include interactions between drilling, extracting, and/or safety operations at the resource site.

Furthermore, regulations may require monitoring of carbon storage systems to demonstrate to regulatory bodies that the activities and structures surrounding said carbon storage systems are safe and proceeding as planned. This cycle, according to some embodiments, is termed the measure-monitor-verify (MMV) cycle or plan. In particular, the MMV plan can include conformance operations with associated time lapse measurements undertaken to confirm that fluid migration activity (e.g., CO₂ plume migration) conforms to a developed subsurface model. Furthermore, the MMV plan also includes containment operations comprising obtaining measurements that verify the stability of the developed subsurface model and/or robustness of an implemented storage complex based on the subsurface model. The MMV plan could be built or developed to blend together a number of discreet measurements acquired from the implemented storage complex using a variety of tools. In particular, the MMV plan, according to one embodiment, is implemented to account for several domains including an atmosphere domain, a biosphere domain, a hydrosphere domain, and a geosphere domain associated with the storage complex. Furthermore, the MMV plan can also account for the different phases of the injection (e.g., fluid injection) including pre-injection operations, injection operations, post-injection operations, and closure operations. The costs associated with the MMV plan can be large and span several decades. The disclosed subject-matter provides methods, systems, and computer programs that reduce these costs and also satisfy regulatory requirements in an optimal and cost-effective fashion. According to one embodiment the disclosed techniques may be applied to one or more of the aforementioned domains including a geosphere domain, the atmosphere domain, the biosphere domain, and the hydrosphere domain.

According to one embodiment, the disclosed approach develops a monitoring system that re-imagines 4D seismic acquisition and moves away from a 4D imaging objective to a 4D detection objective. In particular, a sparse acquisition geometry may be generated that samples data associated with the subsurface within which fluid is to be stored such that the sampled data enables the verification of whether a stored fluid (e.g., CO₂, CH₄, and/or some other gas) is in place or not. Thus, this approach does not require the creation of an image of the subsurface, but to simply verifies whether a stored fluid is present within a given sector of the storage complex (e.g., subsurface storage complex). According to one embodiment, the disclosed technology links the sampled data to a subsurface model on which the storage complex is based. Specifically, measurement(s) including sampling subsurface data provides adequate information to not only confirm the presence of the stored fluid plume (e.g., gas plume) (or not) but to also feed back into the subsurface model and thereby refine and adjust the subsurface model throughout the lifecycle of the storage complex. In some implementations, the disclosed technology includes designing geometry parameters, selecting appropriate sensors to track or measure the designed geometry parameters, developing a mechanism to update the properties of the subsurface model based on the tracking, executing history matching operations on the subsurface model using the mechanism, executing update or optimization operations on the subsurface model based on the history matching operations, and executing verification operations on the updated subsurface model to ensure that the subsurface model is within a specified tolerance threshold value. If the subsurface model is not within the tolerance threshold value, the measurements from sensors may not be accurately matched to the subsurface model. This mismatch can be triggered or flagged to initiate a corrective process that leverages additional data acquisition operations or efforts that drive the optimization and design of the subsurface model and/or the storage facility based on same. According to one embodiment, the sensors used for sampling and/or tracking and/or measuring the designed geometry parameters include distributed acoustic sensors (DAS). For example, the DAS sensors may sample the designed geometry parameters associated with the subsurface and thereby create a subsurface layout that meets sampling requirements associated with the subsurface model update operations. In addition, the disclosed approach also leverages real-time or near-real time data associated with 4D full waveform inversion (FWI) operations and/or from 4D Machine Learning associated with plume property prediction from pre-stack data associated with a stored fluid. Furthermore, the disclosed embodiments also incorporate prototype workflows that leverage machine learning techniques to enable multiple realizations of the subsurface model which is fungible, organic, or otherwise elastic or tweakable to ensure convergence on an optimal subsurface model within a short time (e.g., in near-real time, between 1 and 10 hours, or at least 10 hours, etc.) and that accurately characterizes the subsurface for fluid storage operations. A plurality of verification operations may be executed on the optimal subsurface model as further discussed elsewhere herein.

### Characterization

According to some embodiments, the steps required to adequately characterize a site for fluid or carbon storage includes the creation of a static geological model, upon which dynamic modelling coupled with geomechanical simulations can be undertaken, with sensitivity analysis, in order to identify and quantify the risks relating to the integrity of the site and storage complex. Dynamic simulators may be used to provide answers to questions such as storage capacity, injectivity and containment. In one embodiment, these simulators consider different storage scenarios such as aquifers, depleted oil and gas fields/reservoirs, or other enhanced oil recovery (EOR) schemes. Furthermore, these simulators may also consider the complex multiphase nature of the fluid to be stored (e.g., CO₂) as well as simulate over long timescales and integrate or couple the simulators with geomechanical analysis. Geomechanical simulations by the simulators may be used to evaluate the strength of the rock given pore pressure changes for different injection scenarios as well as mitigate residual risks associated with failure and/or fault reactivation. As discussed, seismic data may be used to create the static model. It is also worthy of note that the validation of the dynamic simulations may form part of the MMV processes. Rock physics may form the bridge between the simulator and seismic domains and may therefore include an area of ongoing research.

### Monitoring Measurement and Verification

According to some implementations, the monitoring strategy may be incorporated into the planning phase as seen in FIG. 1A. When considering the design of the MMV strategy, objectives of the measurements being captured may be reviewed. FIG. 1C describes some of the technologies applied within a carbon or fluid or gas storage MMV and groups them under multiple objectives. In particular, FIG. 1C provides a summary of monitoring techniques 108, summarised under monitoring objectives (e.g., assurance or verification), area of investigation (e.g., surface, borehole, near borehole or reservoir) and, phase of project (e.g., baseline, injection, post injection and long term). The first objective 110 relates to assurance which may include assuring the key stakeholders that the carbon or fluid storage related activity is not having any unwanted outcome to the environment. In this way, a link to containment of the fluid or carbon may be established. The second objective 112 may include to verify the carbon or fluid storage related activity is progressing as planned based on acquired measurements confirm that the carbon or fluid storage activity is conformable to the predicted activity and that the subsurface model is therefore sufficiently accurate. Under these two objectives 110, 112 are listed seven measurement types that can be combined to verify that these objectives have been achieved and therefore address the regulatory requirements. For the EU, this would be, providing a comparison between the actual and modelled behaviour of stored fluid (e.g., CO₂) relative to a water formation and/or a storage site as well as detecting significant irregularities, detecting migration of fluid, detecting leakage of stored fluid, detecting significant adverse effects for the surrounding environment, assessing the effectiveness of any corrective measures, and updating the assessment of the safety and integrity of the storage complex in the short and long term.

It is appreciated that not every technique is valid for every site, and the design process, according to some embodiments, may be designed using a risk-based approach whereby the site-specific risks are identified, and the appropriate blend of technique and data type is derived to measure, monitor, and verify them. The area of the subsurface sampled by each measurement needs to be considered and accounted for. The timeline/phase of the injection cycle also needs to be considered in terms of the resolution required, the areas sampled, and the value acquisition will bring. For example, in the early stages of injecting the fluid (e.g., CO₂), the fluid or gas plume may be localised around a well, and so the monitoring data may be used to calibrate the initial dynamic models and can also be used to optimise injection rates. In the latter stages of injection, or in the post injection phase, the subsurface model may be calibrated and further analyzed for insights. Therefore, the optimisation of injection rates may be less critical, and the fluid or gas plume may likely extend over an area that is far outside of that sampled by borehole measurements.

The role of seismic data within this holistic monitoring regime may be to assist with the verification or conformance objective of CCS operations. The various MMV techniques in this disclosure can be grouped into three broad categories: borehole techniques, near-hole techniques, and field wide techniques. In the initial injection phase, borehole and surface-to-borehole seismic data may be used to provide a first calibration of the subsurface model and as the fluid (e.g., CO₂) and pressure plume expand outside of the area which can be sampled by borehole seismic, a reversion to surface seismic data may be used to provide information that verify the migration of the fluid or gas plume and the absence of leakage.

While seismic data (e.g., borehole data and surface data) has been useful in monitoring fluid (e.g., CO₂) injection operations and has been proposed as part of the MMV plans for the key CCS projects, these techniques should not be used in isolation. OPEX costs remain a consideration to the viability of each CCS project and the overall scalability of the CCS contribution to the net zero objective. The use of non-seismic methods, such as microgravity may be considered in order to reduce the frequency at which the seismic monitor survey is deployed.

A full feasibility design study may be undertaken, according to some embodiments, to identify the expected time-lapse response to fluid (e.g., CO₂) injection. This can identify, in a phased manner, which methods can detect the migration of fluid (e.g., CO₂) within the storage unit as well as which methods are best able to detect leakage outside of the storage unit. It is appreciated that the seismic technique may not always be effective at identifying fluid in place data. The viability of the seismic technique is dependent on the in-situ conditions and needs to be validated through modelling as part of the design process. For example, the seismic response generated when injecting fluid into a saline aquifer may be very different to the seismic response generated when injecting the fluid into a depleted hydrocarbon field. While the case of injection into a saline aquifer may present a significant change in the seismic response, the equivalent case with a depleted oil reservoir scenario may present a much more suitable seismic response. This might either limit the viability of the seismic technique or require careful consideration in the acquisition and interpretation stages. This process may be driven by a forward modelling approach and a non-seismic techniques should be included in such a process. Importantly, as part of the forward modelling, sensitivity analysis may be undertaken to determine a threshold at which a fluid leak can be detected, for any given depth. The multiphase nature of fluid (e.g., CO₂) may be analyzed for insights that may be incorporated into the analysis.

Additionally, while seismic methods may be sensitive to fluid (e.g., CO₂) presence, the fluid (e.g., CO₂) saturation quantification using seismic techniques may be less reliable than EM or gravity methods according to some embodiments. This needs to be considered when addressing monitoring objective(s). According to one embodiment, this disclosure provides mechanisms for monitoring movement within the storage unit. In addition, the disclosed techniques enable verifying saturation levels within the storage unit. Furthermore, the disclosed approach enables detecting leakage outside of the storage unit.

Given that the MMV strategy is in place to assure the safety of the operations and verify that they are proceeding as predicted, there is a need to deploy methodologies and technologies that have been proven to be effective. Given the differences between the objectives of time-lapse monitoring for hydrocarbon production and the objectives of time-lapse monitoring for fluid storage or carbon storage operation, there is opportunity to innovate and re-evaluate the cost effectiveness of seismic monitoring, especially in the post-injection phase of the carbon storage or fluid storage project.

Conceptually, when the use of time-lapse seismic data for the monitoring of hydrocarbon production are compared, some distinctions between said time-lapse seismic data may lead to opportunities. In the first instance, a storage unit based on, for example, screening and MMV criteria may be chosen. This should limit, according to some embodiments, the complexity of the storage area. Additionally, the objective is not to only seek out and understand increasing levels of complexity (e.g., as production rates drop) or identify bypassed fluids in a storage complex, but to also compartmentalised subsurface structures such as reservoirs. In addition, the objective also includes confirming the migration of the fluid plume (e.g., CO₂) plume, the absence of leakage and the conformance to the subsurface model relative to the storage facility within the subsurface. A third consideration may include managing the evolution of the monitoring design. In a hydrocarbon production scenario, operations that increase the level of monitoring such as the production rate decreases and the need to better describe the subsurface to extract more value out of the CAPEX already invested is justified may be executed. Conversely, within fluid or carbon storage operations, the monitoring plan may be an upfront requirement. This provides a desirable scenario where planning of a monitoring strategy in place for the entirety of the project may be implemented. As a result, an adaptive cost-effective monitoring solution based on the phase of the fluid or carbon storage operations (i.e. injection, post-injection, closure) via automation and integration may be adopted. Given the upfront investment in baseline data and a geological environment lacking in significant complexity (e.g., relative to newly discovered hydrocarbon sites), the disclosed techniques enables the leveraging of artificial intelligence or machine learning techniques to assist in the processing and interpretation of time-lapse data and the accompanying evolution of time-lapse acquisition geometry from dense to sparse data points within the subsurface. The disclosed techniques also focuses on OPEX cost together with the predicted scale-up of sites requiring monitoring resulting in the investigation and development of new acquisition sensors and technology.

According to one embodiment, distributed acoustic sensing (DAS) technologies are used for the disclosed techniques. In particular, the DAS technologies may be optimized to provide an integrated borehole monitoring solution, providing multi-purpose measurements across different domains and objectives within the fluid storage or carbon storage associated with the MMV program. Furthermore, the DAS technologies may be deployed to capture surface seismic data for seismic monitoring operations. The use of surface deployed DAS (S-DAS) based on the disclosed methods shows significant potential as a sensor with which to acquire seismic data to monitor fluid or gas plume movement.

According to some embodiments, having a purposed designed, high trace density baseline seismic survey ahead of injection can provide a training data set for machine learning techniques. Neural networks may be leveraged to predict the plume extent directly from a pre-stack seismic data. Initial trials on realistic synthetic data can indicate predicted plume extent relative to the true model and that 4D noise related to mis-positioning and acquisition variations adequately suppressed by applying a non-repeatable noise suppression algorithm thereby training the dataset in areas outside of anticipated data changes. While this is unlikely to provide a level of accuracy comparable to traditional time-lapse processing methodologies, it does provide the potential to deliver a 4D outcome that can be used to determine if further additional processing or/and acquisition is required as part of a semi-automated, adaptive monitoring workflow. In addition, using the machine learning techniques can decrease the sampling of the monitor survey in some cases. The neural network, for example, can be trained using a baseline data set based on early monitoring surveys and the knowledge or insights obtained from the training can be used to reconstruct subsequent monitoring surveys that are acquired with a geometry that has a lower source and receiver effort. Initial results indicate that the drop in accuracy of the subsequent prediction may be within acceptable limits for the delineation of fluid (e.g., CO₂) plume bodies and can also be used to quantify a relationship between sample density and the subsurface model update. Machine learning has several other key opportunities to increase efficiency, reduce costs, and assist in the scale up of fluid or other CCS project development. These approaches may include the automation of seismic interpretation, fault interpretation, capturing subsurface structure and reservoir property uncertainty, and, the screening of legacy wells at a basin scale to assess risk and build an understanding of well integrity as part of the initial site selection criteria.

As can be seen in FIG. 1D, the workflows 118 for GS campaign design and execution as disclosed may involve modeling operations that define/build specific scenarios 120 associated with a given resource site. The GS campaign design and execution may also include, parameterizing a GS model 122 using a computation engine (e.g., the model factory) and executing the GS model in one or more simulators 124 following which analysis operations may be executed on the modeling results to generate one or more reports and/or automatically or semi-automatically configure equipment associated with GS operations at a given resource site. In particular, the disclosed technology allows the testing or simulating, in parallel, multiple physical properties associated with a given resource site across a plurality of geological realizations. The results from these tests may be fed into one or more analysis engines 126 that condenses the vast simulation results into actionable insights and/or configuration settings, and/or safety data that may be used to optimize the configuration and/or operation of GS equipment at a given resource site. This may hone in or otherwise pinpoint precise monitoring techniques to deploy at each stage included in the GS campaign thereby mitigating against GS project risks and operational costs. Using the results from the simulations (e.g., insights from the simulations), adaptive monitoring and/or safety strategies may be seamlessly implemented in conjunction with GS operations at a given resource site.

### Resource Site

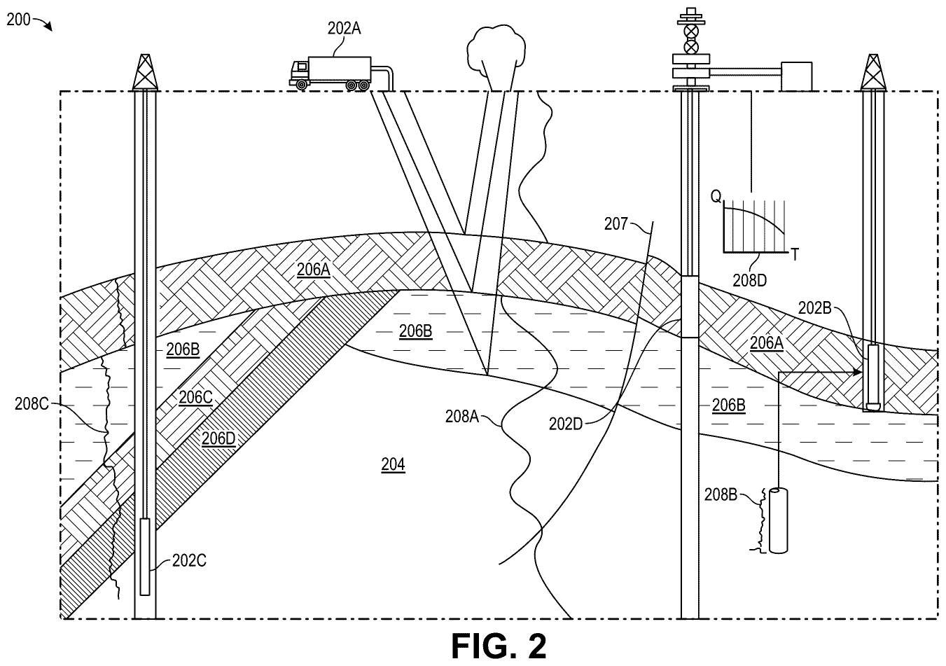

FIG. 2 shows a cross-sectional view of a resource site 200 for which the process of FIG. 1D may be executed. While the illustrated resource site 200 represents a subterranean formation, the resource site, according to some embodiments, may be below water bodies such as oceans, seas, lakes, ponds, wetlands, rivers, etc. According to one embodiment, various measurement tools capable of sensing one or more parameters such as seismic two-way travel time, density, resistivity, production rate, etc., of a subterranean formation and/or geological formations may be provided at the resource site. As an example, wireline tools may be used to obtain measurement information related to geological attributes (e.g., geological attributes of a wellbore and/or reservoir) including geophysical and/or chemical information. For example, the chemical information may include chemical information associated with the subsurface and/or chemical information associated with the surface/above ground areas of the resource site 200. In some embodiments, various sensors may be located at various locations around the resource site 200 to monitor and collect data for executing the process of FIG. 1D. In other embodiments, the techniques disclosed herein may be applied to surface seismic monitoring applications, surface gravity applications, surface electromagnetic applications, surface ground heave applications, and surface measurement of induced seismicity applications. According to some implementations, the disclosed techniques may be applied to remote sensing applications (e.g., satellite-based measurements), subsea applications associated with permanent sensors, temporary sensor applications, applications associated with remotely operated vehicles, and applications associated with aerial-based measurements (e.g., performed from planes, helicopters, and/or drones). Such measurements may include Synthetic Aperture Radar data, atmospheric concentration data associated with molecules such as CO₂, CH₄, and/or fluid concentration data associated with fluids or gases within the seabed.

Part, or all, of the resource site 200 may be on land, on water, or below water. In addition, while a resource site 200 is depicted, the technology described herein may be used with any combination of one or more resource sites (e.g., multiple oil fields or multiple wellsites, one or more saline aquifers, one or more depleted oil/gas fields, etc.), one or more processing facilities, etc. As can be seen in FIG. 2, the resource site 200 may have data acquisition tools 202a, 202b, 202c, and 202d positioned at various locations within the resource site 200. The subterranean structure 204 may have a plurality of geological formations 206a-206d. As shown, this structure may have several formations or layers, including a shale layer 206a, a carbonate layer 206b, a shale layer 206c, and a sand layer 206d. A fault 207 may extend through the shale layer 206a and the carbonate layer 206b. The data acquisition tools, for example, may be adapted to take measurements and detect geophysical and/or chemical characteristics of the various formations shown.

While a specific subterranean formation with specific geological structures is depicted, it is appreciated that the oil field 200 may contain a variety of geological structures and/or formations, sometimes having extreme complexity. In some locations of a given geological structure, for example below a water line (e.g., aquifer) relative to the given geological structure, fluid may occupy pore spaces of the formations. Each of the measurement devices may be used to measure properties of the formations and/or other geological features. While each data acquisition tool is shown as being in specific locations in FIG. 2, it is appreciated that one or more types of measurement may be taken at one or more locations across one or more sources of the resource site 200 or other locations for comparison and/or analysis. The data collected from various sources at the resource site 200 may be processed and/or evaluated and/or used as training data, and or used to generate high resolution result sets for characterizing a resource at the resource site, and/or used for generating resource models, etc. In one embodiment, the data collected by one or more sensors at the resource site may include data associated with the number of wells of a first reservoir or second reservoir at the resource site, data associated with the number of grid cells of the first or second reservoir, data associated with the average permeability of the first or second reservoir, data associated with the production duration history (e.g., number of years of production) of the first reservoir or second, etc.

Data acquisition tool 202a is illustrated as a measurement truck, which may include devices or sensors that take measurements of the subsurface through sound vibrations such as, but not limited to, seismic measurements. Drilling tool 202b may include a downhole sensor adapted to perform logging while drilling (LWD) data collection. The wireline tool 202c may include a downhole sensor deployed in a wellbore or borehole. Production tool 202d may be deployed from a production unit or Christmas tree into a completed wellbore. Examples of parameters that may be measured include weight on bit, torque on bit, subterranean pressures (e.g., underground fluid pressure), temperatures, flow rates, compositions, rotary speed, particle count, voltages, currents, and/or other parameters of operations as further discussed below.

Sensors may be positioned about the storage complex to collect data relating to various storage complex operations, such as sensors deployed by the data acquisition tools 202. The sensor may include any type of sensor such as a metrology sensor (e.g., temperature, humidity), an automation enabling sensor, an operational sensor (e.g., pressure sensor, H₂S sensor, thermometer, depth, tension), evaluation sensors, that can be used for acquiring data regarding the formation, wellbore, formation fluid/gas, wellbore fluid, gas/oil/water included in the formation/wellbore fluid, or any other suitable sensor. For example, the sensors may include accelerometers, flow rate sensors, pressure transducers, electromagnetic sensors, acoustic sensors, temperature sensors, chemical agent detection sensors, nuclear sensor, and/or any additional suitable sensors. In one embodiment, the data captured by the one or sensors may be used to characterize, or otherwise generate one or more parameter values for a high resolution result set used to, for example, generate a resource model or a GS model as the case may require. In other embodiments, test data or synthetic data may also be used in developing the resource model or the GS model via one or more simulations such as those discussed in association with the workflows presented herein.

Evaluation sensors may be featured in downhole tools such as tools 202b-202d and may include for instance electromagnetic, acoustic, nuclear, and optic sensors. Examples of tools including evaluation sensors that can be used in the framework of the current method include electromagnetic tools including imaging sensors such as FMI™ or QuantaGeo™, induction sensors such as Rt Scanner™, multifrequency dielectric dispersion sensor such as Dielectric Scanner™, acoustic tools including sonic sensors, such as Sonic Scanner™ or ultrasonic sensors, such as pulse-echo sensor as in UBI™ or PowerEcho™ or flexural sensors PowerFlex™, nuclear sensors such as Litho Scanner™ or nuclear magnetic resonance sensors, fluid sampling tools including fluid analysis sensors such as InSitu Fluid Analyzer™, distributed sensors including fiber optic. Such evaluation sensors may be used in particular for evaluating the formation in which the well is formed (i.e., determining petrophysical or geological properties of the formation), for verifying the integrity of the well (such as casing or cement properties) and/or analyzing the produced fluid (flow, type of fluid, etc.).

As shown, data acquisition tools 202a-202d may generate data plots or measurements 208a-208d, respectively. These data plots are depicted within the resource site 200 to demonstrate that data generated by some of the operations executed at the resource site 200.

Data plots 208a-208c are examples of static data plots that may be generated by data acquisition tools 202a-202c, respectively. However, it is herein contemplated that data plots 208a-208c may also be data plots that may be generated and updated in real time. These measurements may be analyzed to better define properties of the formation(s) and/or determine the accuracy of the measurements and/or check for and compensate for measurement errors. The plots of each of the respective measurements may be aligned and/or scaled for comparison and verification purposes. In some embodiments, base data associated with the plots may be incorporated into site planning, modeling a test at the resource site 200. The respective measurements that can be taken may be any of the above.

Other data may also be collected, such as historical data of the resource site 200 and/or sites similar to the resource site 200, user inputs, information (e.g., economic information) associated with the resource site 200 and/or sites similar to the resource site 200, and/or other measurement data and other parameters of interest. Similar measurements may also be used to measure changes in formation aspects over time.

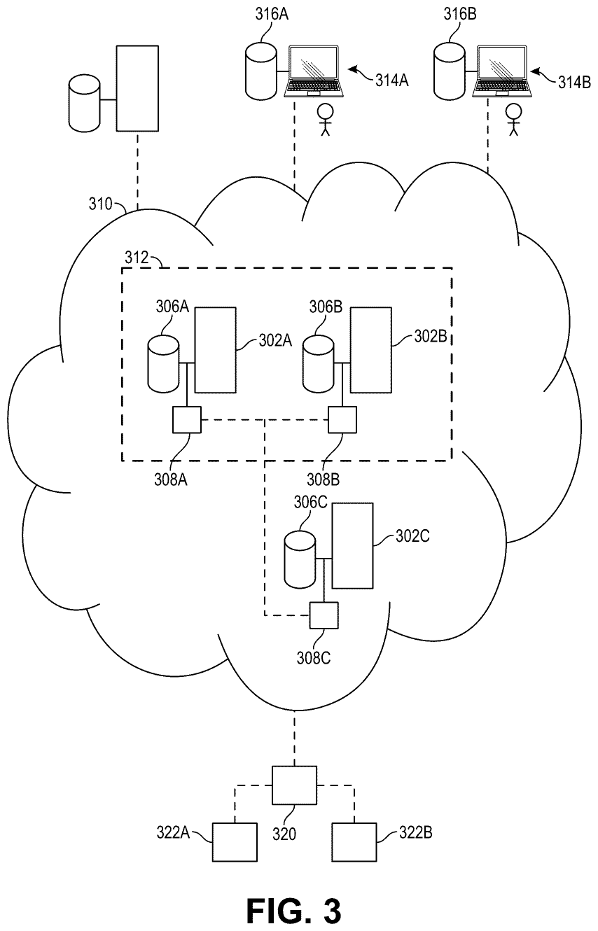

Computer facilities such as those discussed in association with FIG. 3 may be positioned at various locations about the resource site 200 (e.g., a surface unit) and/or at remote locations. A surface unit (e.g., one or more terminals 320) may be used to communicate with the onsite tools and/or offsite operations, as well as with other surface or downhole sensors. The surface unit may be capable of sending commands to the oil field equipment/systems, and receiving data therefrom. The surface unit may also collect data generated during production operations and can produce output data, which may be stored or transmitted for further processing.

The data collected by sensors may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis or for modeling purposes to optimize production processes at the oil field 200. In one embodiment, the data is stored in separate databases, or combined into a single database.

### High-Level Networked System

FIG. 3 shows a high-level networked system diagram illustrating a communicative coupling of devices or systems associated with the resource site 200. The system shown in the figure may include a set of processors 302a, 302b, and 302c for executing one or more processes discussed herein. The set of processors 302 may be electrically coupled to one or more servers (e.g., computing systems) including memory 306a, 306b, and 306c that may store for example, program data, databases, and other forms of data. Each server of the one or more servers may also include one or more communication devices 308a, 308b, and 308c. The set of servers may provide a cloud-computing platform 310. In one embodiment, the set of servers includes different computing devices that are situated in different locations and may be scalable based on the needs and workflows associated with the oil field 200. The communication devices of each server may enable the servers to communicate with each other through a local or global network such as an Internet network. In some embodiments, the servers may be arranged as a town 312, which may provide a private or local cloud service for users. A town may be advantageous in remote locations with poor connectivity. Additionally, a town may be beneficial in scenarios with large networks where security may be of concern. A town in such large network embodiments can facilitate implementation of a private network within such large networks. The town may interface with other towns or a larger cloud network, which may also communicate over public communication links. Note that cloud-computing platform 310 may include a private network and/or portions of public networks. In some cases, a cloud-computing platform 310 may include remote storage and/or other application processing capabilities.

The system of FIG. 3 may also include one or more user terminals 314a and 314b each including at least a processor to execute programs, a memory (e.g., 316a and 316b) for storing data, a communication device and one or more user interfaces and devices that enable the user to receive, view, and transmit information. In one embodiment, the user terminals 314a and 314b is a computing system having interfaces and devices including keyboards, touchscreens, display screens, speakers, microphones, a mouse, styluses, etc. The user terminals 314 may be communicatively coupled to the one or more servers of the cloud-computing platform 310. The user terminals 314 may be client terminals or expert terminals, enabling collaboration between clients and experts through the system of FIG. 3.

The system of FIG. 3 may also include at least one or more oil fields 200 having, for example, a set of terminals 320, each including at least a processor, a memory, and a communication device for communicating with other devices communicatively coupled to the cloud-computing platform 310. The resource site 200 may also have one or more sensors (e.g., one or more sensors described in association with FIG. 2) or sensor interfaces 322a and 322b communicatively coupled to the set of terminals 320 and/or directly coupled to the cloud-computing platform 310. In some embodiments, data collected by the one or more sensors/sensor interfaces 322a and 322b may be processed to generate a one or more resource models (e.g., reservoir models) or one or more resolved data sets used to generate the resource model which may be displayed on a user interface associated with the set of terminals 320, and/or displayed on user interfaces associated with the set of servers of the cloud computing platform 310, and/or displayed on user interfaces of the user terminals 314. Furthermore, various equipment/devices discussed in association with the resource site 200 may also be communicatively coupled to the set of terminals 320 and or communicatively coupled directly to the cloud-computing platform 310. The equipment and sensors may also include one or more communication device(s) that may communicate with the set of terminals 320 to receive orders/instructions locally and/or remotely from the resource site 200 and also send statuses/updates to other terminals such as the user terminals 314.

The system of FIG. 3 may also include one or more client servers 324 including a processor, memory and communication device. For communication purposes, the client servers 324 may be communicatively coupled to the cloud-computing platform 310, and/or to the user terminals 314a and 314b, and/or to the set of terminals 320 at the resource site 200 and/or to sensors at the oil field, and/or to other equipment at the resource site 200.

A processor, as discussed with reference to the system of FIG. 3, may include a microprocessor, a graphical processing unit (GPU), a microcontroller, a processor module or subsystem, a programmable integrated circuit, a programmable gate array, or another control or computing device.

The memory/storage media discussed above in association with FIG. 3 can be implemented as one or more computer-readable or machine-readable storage media that are non-transitory. In some embodiments, storage media may be distributed within and/or across multiple internal and/or external enclosures of a computing system and/or additional computing systems. Storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs), BluRays or any other type of optical media; or other types of storage devices. “Non-transitory” computer readable medium refers to the medium itself (i.e., tangible, not a signal) and not data storage persistency (e.g., RAM vs. ROM).

Note that instructions can be provided on one computer-readable or machine-readable storage medium, or alternatively, can be provided on multiple computer-readable or machine-readable storage media distributed in a large system having possibly plural nodes and/or non-transitory storage means. Such computer-readable or machine-readable storage medium or media is (are) considered to be part of an article (or article of manufacture). The storage medium or media can be located either in a computer system running the machine-readable instructions, or located at a remote site from which machine-readable instructions can be downloaded over a network for execution.

It is appreciated that the described system of FIG. 3 is an example that may have more or fewer components than shown, may combine additional components, and/or may have a different configuration or arrangement of the components. The various components shown may be implemented in hardware, software, or a combination of both, hardware and software, including one or more signal processing and/or application specific integrated circuits.

Further, the steps in the flowcharts described below may be implemented by running one or more functional modules in an information processing apparatus such as general-purpose processors or application specific chips, such as ASICs, FPGAs, PLDs, GPUs or other appropriate devices associated with the system of FIG. 3. For example, the flowchart of FIG. 1D as well as the flowcharts below may be executed using a signal processing engine stored in memory 306a, 306b, or 306c such that the signal processing engine includes instructions that are executed by the one or more processors such as processors 302a, 302b, or 302c as the case may be. The various modules of FIG. 3, combinations of these modules, and/or their combination with general hardware are included within the scope of protection of the disclosure. While one or more computing processors (e.g., processors 302a, 302b, or 302c) may be described as executing steps associated with one or more of the flowcharts described in this disclosure, the one or more computing device processors may be associated with the cloud-based computing platform 310 and may be located at one location or distributed across multiple locations. In one embodiment, the one or more computing device processors may also be associated with other systems of FIG. 3 other than the cloud-computing platform 310.

In some embodiments, a computing system is provided that includes at least one processor, at least one memory, and one or more programs stored in the at least one memory, such that the programs include instructions, which when executed by the at least one processor, are configured to perform any method disclosed herein.

In some embodiments, a computer readable storage medium is provided, which has stored therein one or more programs, the one or more programs including instructions, which when executed by a processor, cause the processor to perform any method disclosed herein. In some embodiments, a computing system is provided that includes at least one processor, at least one memory, and one or more programs stored in the at least one memory for performing any method disclosed herein. In some embodiments, an information processing apparatus for use in a computing system is provided for performing any method disclosed herein.

### Embodiments

Two major concerns facing all fluid storage projects are development constraints (e.g., financial viability) and reservoir confinement issues. Operators must ensure that injected fluid stays within a given storage site (e.g., reservoir or aquifer) and prove to regulatory bodies that any fluid leakages are detectable and/or reportable. After a baseline for operational safety is established, the operator must ensure injection performance (e.g., fluid injection performance) to secure that the fluid storage project is viable. Furthermore, other challenges associated with fluid storage include reliance or dependence on practices from other activities (e.g., hydrocarbon activities) which may not directly or indirectly align with fluid storage settings or configurations of the fluid storage equipment. According to some implementations, such activities may include abandonment of legacy wells without having a proper seal (e.g., tight fluid seal) in place to prevent fluid leakage or having an incorrect type of seal (e.g., cement seal) and/or workflow in place for plugging fluid emissions. Other exemplary activities include use of chemicals during hydrocarbon extraction that restrict the flow of fluid or result in reactions that harm future fluid injection performance or significant over-pressuring or under-pressuring of the reservoir resulting in structural damage to the storage complex. In addition, there is an expected increase in fluid storage projects worldwide which will likely overtake the available fluid storage resources (e.g., human and nonhuman storage resources) and which can be greatly improved using the techniques disclosed herein. Furthermore, government agencies need to be assured or periodically reassured that any fluid storage models being implemented for a given resource site are predictable and well controlled to comply with safety requirements for all phases (e.g., injection or post-injection phase of fluid storage and management) associated with a GS campaign for the resource site.

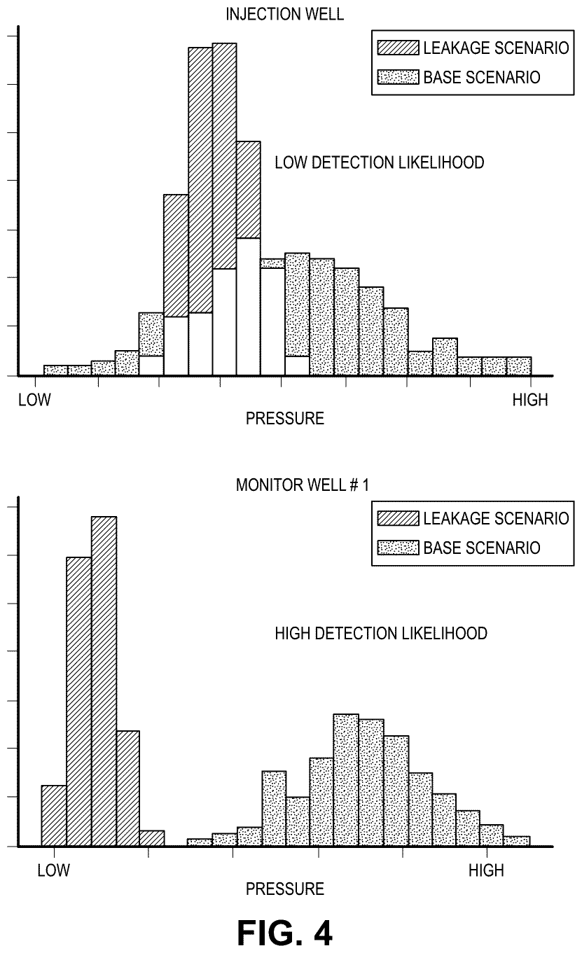

Under a given definition/characterization (e.g., digital quantification, uncertainty parameter quantification, etc.) of subsurface uncertainty, FIG. 4 shows that a measurement, for example pressure, conducted in one well (e.g., injection well) may not be able to distinguish or detect a critical event (e.g., fluid leakage), whereas the same measurement conducted in a different well (e.g., monitor well #1) may distinguish over or detect a critical event. As such, the example shown in FIG. 4 illustrates a spatial deployment (e.g., preferential spatial deployment) of a measurement with respect to monitorability of a critical event (e.g., fluid leakage). In some embodiments, the visualization shown in FIG. 4 indicates a plurality of different measurements (e.g., formation conductivity data or formation pressure data) that highlight which of the plurality of different measurements are more likely to detect the critical event. It is appreciated that the visualization shown in FIG. 4 may enable establishing distinctions between scenarios where there is substantial fluid leakage relative to base scenarios where there is little to no fluid leakage. It is further appreciated that the techniques disclosed herein and which facilitate generation of visualizations such as those shown in FIG. 4 enable the selection of measurement technology and/or spatial deployment of said technology in order to increase the likelihood that a critical event may be detected. In some embodiments, selection of the measurement technology is based on a definition and/or characterization and/or modeling of one or more subsurface uncertainties which determine expected distributions of measurement responses associated with critical events (e.g., fluid leakage). Once a first deployment of measurement technology has been made and some measurements have been obtained, said measurements can be used to refine or otherwise optimize fluid or gas storage (GS) model(s) (e.g., carbon storage (CS) model(s)) and thereby minimize uncertainties associated with said models. In turn, the GS model(s) (e.g., refined GS model(s)) can be used to improve a monitoring plan, and/or control gas monitoring equipment, and/or control containment infrastructure (e.g., valves, pumps, etc.) associated with the GS model(s). According to some implementations, the disclosed technology provides an efficient way for operators to analyze and communicate risk associated with GS operations at a resource site, both internally and externally. This significantly decreases the time of approval from designing a given GS campaign to its execution. The automation of major parts of the disclosed workflows allows operators to run multiple projects using the same resources, allowing the scaling up of the fluid storage activities such as carbon capture, utilization, and storage (CCUS) activities to required volumes. By performing in a continuous loop of feeding measurements from the monitoring GS systems back into generated computing GS model(s) in the operating phase, predictability of such GS model(s) are greatly improved for the next iteration in the testing or simulation phase.

According to some embodiments, the disclosed technology provides a monitoring design tool for subsurface applications associated with GS operations at a resource site. Furthermore, the disclosed technology provides useful monitoring mechanisms that are not only applicable to GS operations but can also be applied to campaigns associated with geothermal solutions, hydrocarbon operations, offshore wind site operations, groundwater exploration activities, and other subsurface monitoring and optimization projects.

According to some embodiments, the disclosed technology builds upon a number of technologies and workflows. For example, the disclosed techniques enhance uncertainty workflows to account for fluid storage use-case of measurement detectability to define a monitoring strategy and to automate comparisons of said monitoring strategy with optimal baseline methods. Moreover, the disclosed technology may incorporate tools such as Agile™ Reservoir Modelling applications to leverage cloud computing resources and thereby accelerate uncertainty assessments associated with GS operations at a resource site. In particular, the systems and methods disclosed leverage a plurality of simulators executing tests in parallel in order to enhance and/or improve a GS model being implemented at a given resource site to accelerate GS project execution times as well as provide timely insights for such projects and reporting same to regulatory agencies. Multiple simulators (and therefore multi-physics techniques) may be combined into similar or dissimilar workflows to determine the most probable measurement detection scenarios that define optimal configurations and/or practices included in a given GS campaign for a resource site and which span all leakage pathways and monitoring methods for said GS campaign. Moreover, the disclosed technology may allow users to customize or otherwise design end-to-end monitoring strategies for GS projects—from fluid injection phases to project handover to other domain experts. In addition, since the software architecture disclosed herein is built around the support of many diverse simulators, the disclosed systems and methods effectively become a high-performance platform for executing simulations or tests associated with a GS monitoring campaign. The architecture defines unified software interfaces that ensure compatibility for the data shared by multiple testing tools or simulators. By openly sharing interface definitions and cultivating an ecosystem around the platform, users can adapt their simulators to securely run on the same platform. As such, the disclosed technology is capable of evolving to become an “app repository” for simulators associated with GS storage operations.

### Workflow for Optimizing Fluid Storage (GS) Operations

At a high level, a user may model the storage complex/site for a given GS operation using a subsurface modelling application (e.g., Petrel™) to generate a GS model. The storage complex or storage site may include areas below ground where fluid is stored and/or a volume of space above a reservoir where fluid is stored and/or an area (e.g., an area adjacent to a resource site) associated with fluid storage operations without reference to an origin of the fluid being stored. The GS model, according to some embodiments, is associated with already captured fluid in which case the systems and workflows disclosed is directed to storage and monitoring of captured fluids or gases such as carbon dioxide, methane, and hydrogen. Furthermore, the GS model may have associated geological uncertainties that may be quantified during the model generation stage based on synthetic data, non-synthetic data such as real-time data or near real-time data captured at the resource site or historical data captured at the resource site, or a combination of synthetic and non-synthetic data. These aspects are further discussed below. The GS model may be released or otherwise liberated into another testing or simulation tool or application (e.g., a Delfi™ digital platform or an Open Subsurface Data Universe (OSDU™) platform. According to some embodiments, the testing tool may detect project information such as offshore/onshore data, well characteristics data, structural information, etc. associated with a resource site to construct a simulation plan for testing the GS model for the resource site.

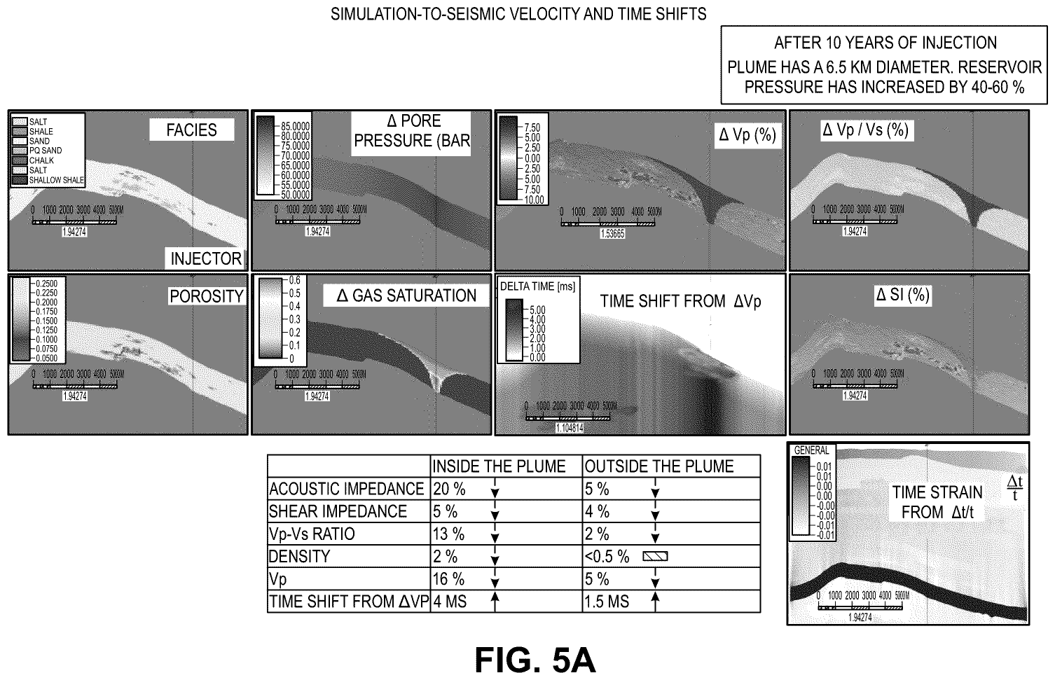

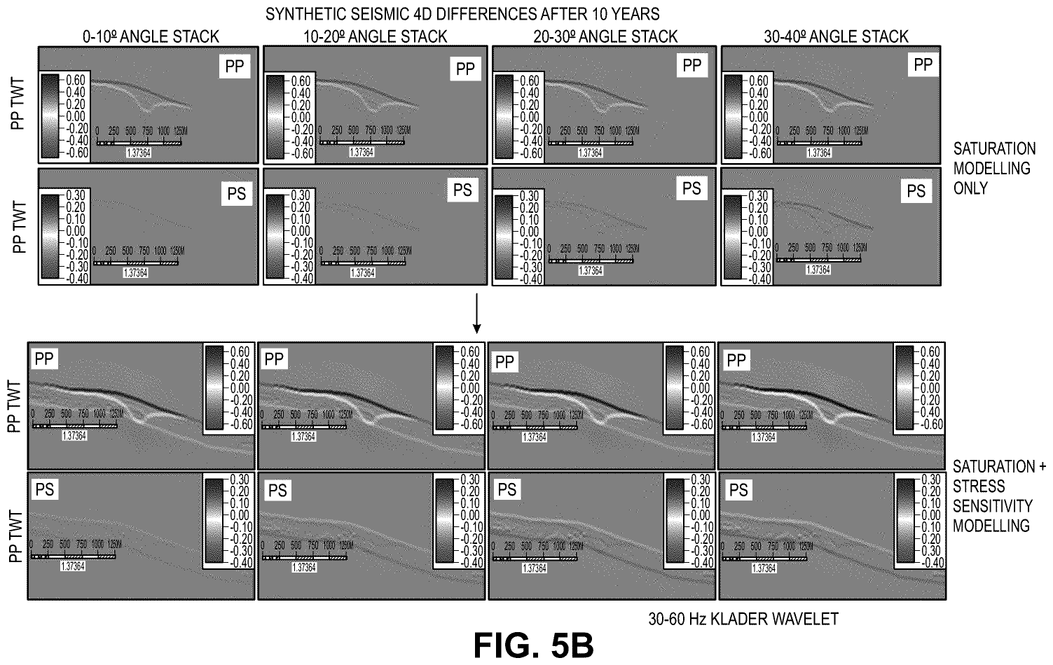

The simulation plan may be reviewed and additional contextual information may be added to same. For example, the additional contextual information may include risk profile data for legacy wells, high-risk zone data for seal leakage scenarios, or monitoring configuration data for controlling monitoring equipment associated with the GS campaign for the resource site. Based on defined scenarios from the previous steps, the testing tool may generate a plurality of required simulation configurations that test the scenarios for a plurality of time periods (days, weeks, months, or years). The simulation configurations may be matched to specific simulators which receive said configurations for testing the GS model. Once the simulators complete testing the GS model using a plurality of scenarios in parallel, the results from such testing are post-processed to determine detectability of fluid concentrations throughout the storage site or storage complex based on each testing method employed by the simulators. Fluid detectability may be computed using computer generated statistical data derived from a plurality of stochastic geological realizations associated with the storage site. For example, the statistical data may include a value indicating a probability of fluid detections such that the value is a number between zero and one. The value, according to some embodiments may be compared to a previously established baseline simulation data. In addition, information about the storage site or storage complex structure (e.g., reservoir extent, layer geometry, etc.) may be used to automatically determine a relative importance of fluid detectability at each location (e.g. fluid detection outside a reservoir may be ranked higher than fluid detections within a reservoir) such that the likelihood of such fluid detection events may be derived from the aforementioned stochastic data. FIG. 5A illustrates several examples of the simulation plan, while FIG. 5B shows the expected seismic response in terms of changes in elastic properties and seismic velocities.

Geophysical measurements can detect the fluid front which may result in a fluid front detection map, a velocity perturbation map, or time shift maps (as indicated in FIG. 5B). In another embodiment, velocity changes or PS reflectivity changes can indicate CO2 injection induced pore pressure changes. Such maps are related to a CO₂ distribution data (e.g., spatial contours detection in one embodiment or 3D probabilistic CO₂ distribution data in another embodiment) of a either location in space or actual change in relative acoustic and/or shear impedance between a CO2 pre-injection baseline and a current state after several years of injection. Geophysical derived fluid detection maps may be compared and co-analyzed with a computer generated fluid detection map. Computer generated detection maps may be generated using an ensemble of simulation results from the plurality of simulations or testing of the GS model and which outlines uncertainty data and fluid detection data associated with one or more sections of the fluid storage site or fluid storage complex combined with an effective medium model for acoustic impedance. The fluid detection map may also show the probability of change associated with acoustic impedance (e.g., caused by injected fluid) being greater than a detectability threshold value, thus indicating regions of the subsurface of the storage site where the movement of fluid can likely be detected using, for example, seismic techniques.

Moreover, the fluid detection maps may include scaling or ranking data that may be directly fed into site-specific design configurations or structuring in order to optimize fluid detectability at the resource site. In addition, the detection maps may include a plurality of colorings that indicate varying degrees of intensity of fluid detection data at multiple locations at the storage site or storage complex at the resource site. For example, the detection map may include a red coloring that indicates a highest likelihood of fluid leakage for a given location at the resource site, a yellow color to indicate a medium likelihood of fluid leakage for other locations at the resource site, and a green coloring indicating a low likelihood of fluid leakage for some locations at the resource or fluid storage site. It is appreciated that the coloring on the detection maps may be a spectrum of colors with red at the extreme end of the spectrum indicating a high likelihood of fluid leakage events and green at the low end of the spectrum indicating a low likelihood of fluid leakage events. A similar process can be derived for pressure detection map where pressure fronts are being detected using changes in elastic properties as shown in FIGS. 5A and 5B.

A benefit of the disclosed approach is the drilling-down into individual simulators and/or workflows to understand fluid detection thresholds based on a plurality of site-specific scenarios and/or simulation conditions. As fluid storage sites become operational so does the actual monitoring data associated with said sites. Previously, only base line monitoring data is available for configuring simulation parameters of the GS model. The additional real-time or near-real-time data or historic data captured at the fluid storage site may be used to improve, enhance, or otherwise optimize the GS model and thereby strengthen the accuracy of the simulation results during subsequent iterations of executing tests or simulations using the GS model based on actual fluid storage site conditions. Anomalies or data abnormalities may be flagged for the user's attention and compared with the GS model parameters (simply referred to as parameters elsewhere herein) before, during, or after execution of the one or more tests on the GS model. Such detection or flagging of data abnormalities may adaptively enable the GS model to be updated or otherwise parametrically revised in order to facilitate accurate detection of fluid events at the storage site.

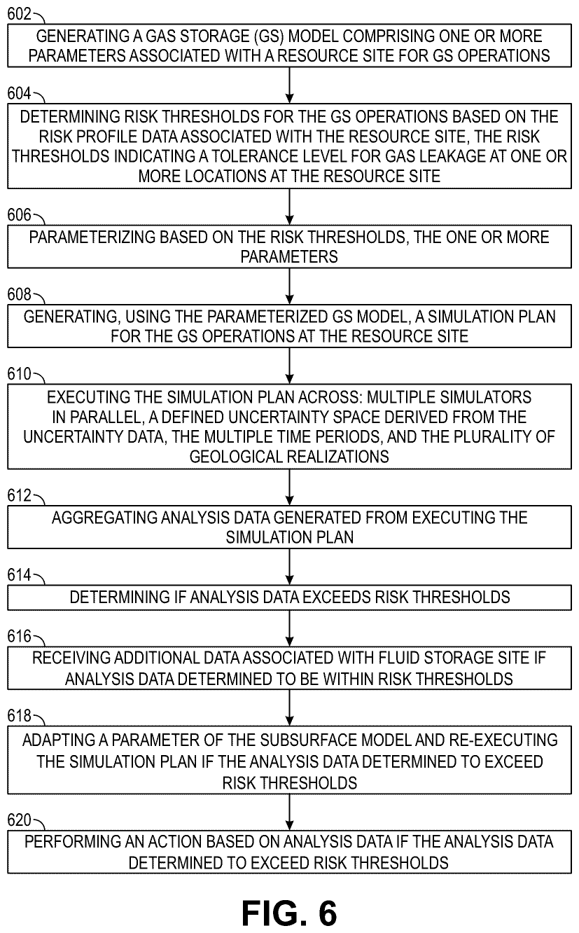

The disclosed technology is directed to methods and systems for optimizing fluid storage (GS) operations at a resource site 600 as exemplified in the flowchart of FIG. 6. It is appreciated that a data processing engine stored in a memory device may cause a computer processor to execute the various processing stages of FIG. 6.

At block 602, the data processing engine may facilitate generating a GS model associated with the resource site such that the GS model includes one or more parameters that characterize at least one of: temporal or spatial distribution data of subsurface geological structures associated with the resource site, uncertainty data indicating varying degrees of uncertainty ascribed to the temporal or spatial distribution data, well log data associated with the resource site, risk profile data associated with the resource site, zone leakage data associated with the resource site, temporal or spatial distribution data of a surface or a subsea terrain associated with the resource site, temporal or spatial distribution data of an atmospheric condition associated with the resource site, or workflow data associated with the resource site.

At block 604, the data processing engine enables determining risk thresholds for the GS operations based on the risk profile data associated with the resource site. In one embodiment, the risk thresholds indicate a tolerance level for fluid leakage at one or more locations at the resource site. The data processing engine may also facilitate parameterizing, based on the risk thresholds, the one or more parameters of the GS model at block 606 using one or more of: synthetic data based on domain-specific information associated with the resource site, or real-time or near-real-time data associated with the resource site that have been captured by one or more sensors deployed around the one or more locations at the resource site.

At block 608, the data processing engine is used to generate, using the parameterized GS model, a simulation plan for the GS operations at the resource site. The simulation plan may indicate at least one of: a plurality of fluid leakage events based on the one or more parameters of the GS model over multiple time periods, a plurality of fluid monitoring plans that track the plurality of fluid leakage events across a plurality of geological realizations, and a plurality of dependent or independent simulations or tests that inform an impact of the fluid monitoring plans over the multiple time periods. Turning to block 610 of FIG. 6, the data processing engine is used to execute the simulation plan across: multiple simulators in parallel, a defined uncertainty space derived from the uncertainty data, the multiple time periods, and the plurality of geological realizations. In some embodiments, evaluation of where new data is to be collected next is analyzed within this step and if needed a geophysical survey design is determined. In some embodiments, the data processing engine may facilitate aggregating, at block 612, analysis data generated from executing the simulation plan. The analysis data may indicate one or more of: fluid concentration data across the one or more locations at the resource site, fluid leakage data across the one or more location at the resource site, and configuration data associated with configuring one or more monitoring systems at the resource site. According to certain embodiments, the analysis data may be determined to be within or exceed the determined risk thresholds, as at block 614. In certain embodiments, if the analysis data has been determined to be within the risk thresholds, a second or updated data set may be received from the fluid storage site as at block 616, thereby restarting the method for optimizing fluid storage operations at a resource site at block 602. In some embodiments newly received data will be collected based on the design mentioned in block 610. Alternatively, according to certain embodiments, if the analysis data has been determined to exceed the risk thresholds, then at least one parameter of the subsurface model may be adjusted and the simulation plan may be re-executed accordingly, as at block 618.

At block 620, an action may be performed that is based on the analysis data if the analysis data has been determined to exceed the risk thresholds. In certain embodiments, the action may include the data processing engine being used to initiate, using the analysis data, generation of a fluid detection map that indicates fluid distribution data associated with the one or more locations at the resource site. The data processing engine may also enable configuring, using the analysis data, the one or more monitoring systems (e.g., carbon dioxide, hydrogen, and methane monitoring systems) at the resource site.

These and other implementations may each optionally include one or more of the following features. The resource site may include a fluid storage site at the resource site including one or more of: an aquifer, a saline aquifer, an oil reservoir, a depleted oil reservoir, a fluid reservoir, or a depleted fluid reservoir. Furthermore, the risk thresholds may quantify one or more of: a minimum amount of fluid leakage that is allowed at the resource site, a specific amount of fluid that is allowed to leak from a primary aquifer into a secondary aquifer, a specific amount of fluid that is allowed to leak into legacy wells, a specific amount of fluid that is allowed to leak from one well into a neighboring well, resolution data of the one or more monitoring systems at the resource site, or regulatory data included in the risk profile data based on emission constraints imposed by regulatory bodies. In addition, the one or more parameters of the GS model may include one or more of: raw data or processed data captured at the resource site, onshore or offshore geological data associated with the resource site comprising seismic data and the temporal or spatial distribution data of subsurface geological structures of the resource site, well characteristics data comprising the well log data, structural data derived from the onshore or offshore geological data, faults data, and interpreted geo-layering data, geophysical data indicating one or more of seismic information, gravity information, electromagnetic information, and nuclear information associated with the resource site, and configuration data associated with the one or more monitoring systems at the resource site. The configuration data, according to some embodiments, includes at least one of: line spacing between sensors at the resource site, and frequency configurations used to tune electromagnetic sensors at the resource site. Moreover, the workflow data associated with the resource site may include: data indicating frequency of executing the simulation plan, data indicating frequency of updating the simulation plan, data indicating time lapse measurements included in the multiple time periods, dynamic post-processing operations data. The dynamic post-processing operations data according to some embodiments includes at least one of: noise removal operations from the captured real-time or near-real-time data associated with the resource site, or inference operations data associated with aggregating the analysis data to provide inferences that indicate the impact of the fluid monitoring plans over the multiple time periods. It is appreciated that the risk profile data includes a quantitative measure of stake holder risk tolerance levels based on domain (e.g., reservoir domain, wellbore domain, etc.) expert data and data associated with subsurface analysis operations. Additionally, the zone leakage data may indicate one or more paths of fluid leakage across the one or more locations at the resource site including leakages across a reservoir at the resource site and leakages across legacy wells including abandoned wells at the resource site.

According to some embodiments, executing the simulation plan includes executing a plurality of simulation streams that test multiple geo-physical properties associated with the one or more locations at the resource site in parallel and concurrently across the plurality of geological realizations. The plurality of geological realizations may include a plurality of GS sub-models of the subsurface associated with the resource site such that the plurality of GS sub-models may indicate at least one of: fault characteristics data associated with the resource site, transmissibility data associated with the resource site, or distribution data indicating statistical characterizations of the subsurface of the resource site. Furthermore, the analysis data may be used to generate a report based on analyzing the simulation results across the defined uncertainty space in different time steps and across different geological realizations included in the plurality of geological realizations. The report may include, for example, one or more of: a visualization indicating the fluid detection map, a matrix indicating efficacy level data for using a plurality of different GS operations at the resource site based on the simulations to determine an optimal GS campaign for the resource site, a plurality of tabular data, a two-dimensional visualization indicating a first monitoring design for optimally monitoring fluid stored at the one or more locations at the resource site, or a three-dimensional visualization indicating a second monitoring design for optimally monitoring fluid stored at the one or more locations at the resource site. The report may also include risk threshold data associated with: the one or more monitoring systems at the resource site, or one or more GS operations at the resource site. In addition, the multiple simulators referenced above may include one or more of: flow-based simulator(s) that depend on pressure measurements within the subsurface of the resource site, electromagnetic simulator(s) that depend on formation resistivity data within the subsurface at the resource site, and nuclear simulator(s) that predict responses of certain nuclear measurement(s) within the subsurface at the resource site, including but not limited to pulsed-neutron methods simulator(s) and/or nuclear magnetic resonance (NMR) simulator(s). In some embodiments, the multiple simulators include geomechanical simulator(s) that predict subsurface responses to changes in mechanical conditions at the resource site, including simulators that simulate compaction or expansion of a reservoir (e.g., oil or fluid reservoir, depleted oil or fluid reservoir) associated with the resource site. The multiple simulators may also include electric simulator(s) that predict direct or alternating current responses to changes in subsurface conditions, including changes to electric conductivity within reservoir layers associated with the resource site. In addition, the multiple simulators may include acoustic simulator(s) that depend on acoustic properties of the subsurface at the resource site. It is appreciated that simulations associated with the multiple simulators may include a plurality of simulation methods that can either be executed in an in-situ simulation state or in an inverse state. In the in-situ state, for example, a parameter associated with the GS model may be directly calculated using computational methods and based on previous simulator results. This provides a direct value of a quantity, for example, in the subsurface of the resource site. However, when using other geophysical methods measure properties such as a magnetic response, an averaging operation may be executed over a large number of data points associated with GS locations at the resource site since the magnetic wave travels through a given volume before arriving at the area of interest (e.g. from the surface to a reservoir or from a borehole to a specific layer) associated with the resource site. To recover the parameter of interest, the measured response may be subjected to a process such as a geophysical inversion process which uses a series of models/relations to translate the measured response to the parameter of interest. According to one embodiment, results from executing one or more of the multiple simulators can be used in their raw form or may be subjected to post-processing operations such as a geophysical inversion workflow.

According to some implementations, the one or more parameters of the GS model characterize one or more of: surface seismic data, surface gravity data, surface electromagnetic field data, surface ground heave data, and surface measurement data indicating induced seismicity. In addition, the data processing engine referenced in FIG. 6 may facilitate generating, using the analysis data, a report including one or more of: a plurality of tabular data, a two dimensional visualization indicating a first monitoring design for optimally monitoring fluid stored at the one or more locations at the resource site, or a three-dimensional visualization indicating a second monitoring design for optimally monitoring fluid stored at the one or more locations at the resource site. In some embodiments, parameterizing the one or more parameters of the GS model includes updating grid resolution data for at least one parameter included in the one or more parameters of the GS model.

In some implementations, the fluid storage operations are associated with storing fluid including at least one of: carbon dioxide gas, hydrogen gas, and methane gas. Furthermore, a phase of the stored fluid may be based on one or more of: a depth within a subsurface (e.g., fluid storage complex) of the resource site within which the fluid is stored, and pressure within the subsurface of the resource site within which the fluid is stored. It is appreciated that leakages of fluid from the storage complex may result in the leaked fluid changing phase due to pressure differentials between the pressure within the storage complex relative to pressures within the leakage zones around the storage complex.

### Workflow for Monitoring Stored Fluid

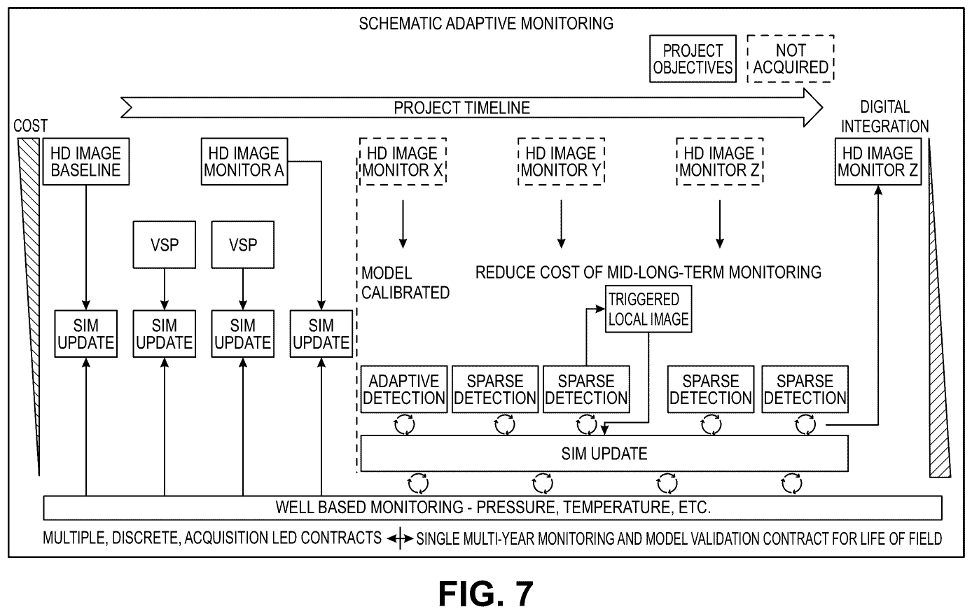

FIG. 7 shows an exemplary flowchart showing a departure from discrete acquisition of data such as vertical seismic profiling (VSP) data, high density surface seismic (HD seismic data acquired prior to simulation and includes baseline data, and HD monitoring data. In particular, this departure may also include moving away from discrete updates of the subsurface model to a system of sparse detection and automated and/or semi-automated and/or efficient update of the subsurface model. It is appreciated that the left axis of FIG. 7 shows implementation effects that result in lower cost while the right axis of FIG. 7 shows the improved digital integration impacts from implementing the disclosed techniques.

In one embodiment, the disclosed approach streamlines measure-monitor-verify (MMV) operations for fluid storage. In particular, the MMV operation objectives including maintenance and compliance operations are further enhanced by the disclosed approach to ensure that fluid storage operations are proceeding as planned and that fluid levels are at projected levels based on the subsurface model. In particular, the disclosed techniques enable the efficiencies in history matching operations associated with the subsurface model by leveraging new and sparse data measurements associated with the subsurface model thereby impacting the cost of data acquisition and hence the overall operating costs of the MMV fluid operations. This is particularly beneficial as sparse data is used instead of a full spectrum of subsurface and/or surface data.

According to one embodiment, the disclosed technology includes the following processing stages associated with MMV operations:
generating a baseline data (e.g., high resolution baseline data) enabling usage of a Synthetic Seismic Volume Generation Software (Sim2Seis) workflow or simulation tool;
executing a detailed simulation of an injection scenario based on parameterizing a subsurface model based on the baseline data;
designing a detection campaign based on the simulation including:
   detecting that a seismic data set aimed at monitoring subsurface changes due to fluid plume changes, such that a flag (e.g., quantitative (e.g., 1 or 0) or a qualitative flag (e.g. yes/no) is raised with respect to the presence and/or absence of fluid in the subsurface (e.g., ground). The detection operation may be adapted based on an expected signal-to-noise ratio and a response of the Sim2Seis simulation using the subsurface model relative to expected fluid plume changes due to fluid injection into the subsurface. The output of a detection campaign may provide an indicator of the presence of fluid at given multidimensional locations for a given time set. It is appreciated that this detection approach is cost-effective and is more rapid than full 4D imaging operations or efforts;
executing of parameter detection during injection operations included in the simulation;
executing compliance operations with pre-drill scenario checkup including:
   evaluating fluid presence with respect to an injection plan to verify and/or trigger quality assurance flags when simulation and field observation data are in agreement;
   executing operations associated with reassurance of the next survey, including:
   analyzing and generating regulatory requirements associated with the subsurface model of the next survey, and
   designing and conforming the subsurface model associated with the next survey to comply with said regulatory requirements;
Non-compliance scenario:
   In case of deviation from Sim2Seis simulation operations (e.g., the plume location is not in agreement with flow simulation), execute one or more of:
      updating the subsurface model based on back projection of detection information using a fluid flow simulation,
      executing an adaptive monitoring operation including: a survey design operation adapted to the latest information and aimed at addressing the subsurface uncertainty associated with the subsurface model and thereby maximize assurance and compliance, such that:
      the subsurface model is updated,
      regulatory compliance is preserved,
      subsurface uncertainty is reduced and safe operation is enabled, and
      adaptive monitoring strategy is redesigned.

### Adaptive Monitoring

The disclosed adaptive monitoring offers a shift in the monitoring approach for fluid or carbon storage sites or facilities (e.g., subsurface facilities). For example, the disclosed approach shifts from a 4D seismic reservoir monitoring solution relying on full reservoir production and monitoring to a plume centric approach which tracks the progress of the fluid (e.g., CO₂) plume through a focused and/or targeted detection scheme or localized area within the subsurface (e.g. subsurface fluid storage facility). According to one embodiment, a subsurface model, built and maintained to enable a comparison between an actual and modeled behavior of stored fluid (e.g., CO₂) relative to subsurface structures such as water or fluid formations within the subsurface (e.g., fluid storage facility in the subsurface). Through a process of risk analysis and survey design, an adaptive data acquisition strategy can be established, moving from an accurate high-density baseline and first monitor surveys to calibrate the subsurface model (in tandem with well-based measurements) towards sparser, targeted, multi-domain measurements to confirm adherence to the subsurface model.

For the avoidance of doubt, in varying implementations according to the presentation disclosure, the workflows and techniques disclosed herein may be used with respect to gasses, fluids, and/or combinations of these in varying phases.

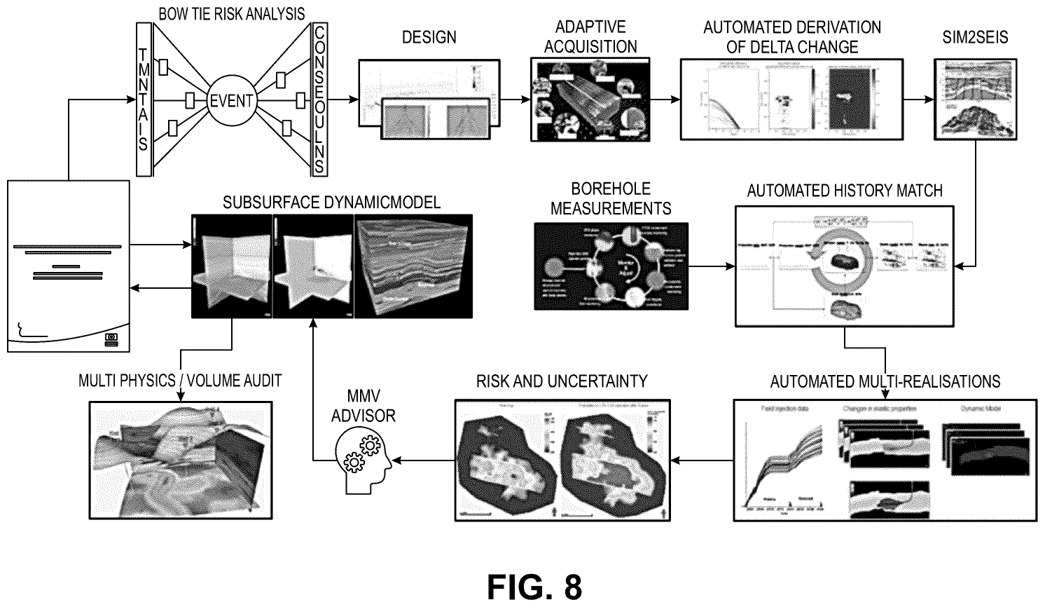

In some cases, the disclosed approach facilitates the identification of significant irregularities associated with the subsurface model. For example, the irregularities may include data which includes data that is not predicted by the subsurface model during the simulations. Examples for such irregularities can be seismic amplitude data changes in places within the subsurface that are not predicted by the flow simulations or the subsurface model and which arrive at different times relative to expected different spatial distribution data associated with the subsurface model. These irregularities can trigger additional targeted acquisition. Prioritizing the link back to the subsurface simulation model may enable this process to leverage opportunities and thereby optimize the link between automation or semi-automation of the key fluid processes within the subsurface including identification of the 4D change/plume extent, integration of the production data and seismic data to improve the history match and/or quantification of the match or mismatch through uncertainty analysis. These aspects are further depicted in the workflow of FIG. 8 which shows a workflow for implementing the disclosed adaptive monitoring regime.

Fluid capture and storage or carbon capture and storage (CCS) operations have been identified as a key enabler to meet net zero targets. The process of identifying, characterising and a fluid monitoring storage facility (e.g. fluid storage facilities within a subsurface) may be reliant on cross domain geological and geophysical technologies, workflows, and expertise. Within this, seismic data has a role to play through the lifecycle of the carbon or fluid storage project. Legacy seismic data can enable regional screening of fluid storage capacities. Newly reprocessed seismic data can support the characterisation of the priority storage areas and other design considerations while, new acquisition of seismic data can help minimise some outstanding uncertainty or risk within the reservoir or overburden (e.g., overburden indicating sedimentary column data relative to a subsurface structure such as a reservoir all the way to the surface), while also forming an ideal baseline for future monitoring. Carbon or fluid storage regulations have highlighted the requirement for understanding the subsurface before implementation activities are executed. To do this, the utilization of the available seismic data may be used prior to the commencement of fluid (e.g., CO2 injection) operations.

Fluid or CS MMV is a broad, cross discipline undertaking and requires a risk-based approach. The technologies deployed provided in this disclosure can depend on identified risks to safe storage and containment and can consider site geology, volume of fluid (e.g. CO₂) and the regulatory framework applied to the storage facility. Within this, seismic data (e.g., borehole seismic data and/or surface seismic data) may be used in characterizing the near-well area, for initial calibration of the subsurface model, and verifying fluid (e.g., CO₂) plume and pressure movement and detecting leakage. The viability of the seismic technique may be dependent on the in-situ conditions within the subsurface and needs to be validated through modelling as part of the design process (e.g. deployment to monitor injection into aquifers versus deployment to monitor injection into depleted fields). Where the seismic technique is shown to give a recordable signal that can be directly linked back to subsurface changes, opportunities exist to improve the cost effectiveness of seismic data within the monitoring system. The disclosed approach also includes the use of fiber optic cable deployed horizontally at the surface of the subsurface within which the fluid storage facility is located to record active and/or passive seismic data as well as use machine learning techniques to accelerate the time-lapse interpretation for use in monitoring fluid (e.g., CO₂) plume movement and leakage as well as optimize and streamline the seismic history matching process. These developments combine to provide an integrated digital solution that enables a cost-efficient, adaptive monitoring system to verify safe carbon storage operations.

According to one embodiment, model data including one or more of geophysical data, gravity data, electromagnetic field data, borehole data, reservoir data, or well log data may be used to generate a subsurface model. The various data, according to one embodiment may be captured by one or more sensors deployed at a resource site associated with fluid storage operations. Furthermore, the generation of the subsurface model may be based on using one or more of the aforementioned data to generate a stratigraphic framework included in the subsurface model. The stratigraphic framework may have static and/or dynamic properties including horizon parameters derived from seismic data, fault parameters (e.g., fault transmissivity parameters) derived from seismic interpretation operations (automatic or otherwise), lithography parameters derived from well log data and/or geostatistics data and/or seismic data obtained from seismic inversion operations, porosity parameters derived from well log data and mapped in space based on seismic inversion or geostatic operations and/or machine learning or artificial intelligence operations, porosity or permeability parameters indicating relationships based on rock physics or laboratory tests on subsurface samples.

In one embodiment, the created subsurface model may be subjected to one or more simulations or tests based on the above parameters. The simulations, for example, provide response data based on dynamic values associated with or ascribed to the various parameters during the simulation. The response data, for example, may indicate deviation information or irregularities data based on predictions or forecasting operations made by the subsurface model during the simulation relative to established thresholds for the subsurface model. In particular, the deviations data can trigger update operations to the subsurface model based on updating one or more of the aforementioned parameters to maintain, keep, or transition the subsurface model in a stable state.

According to exemplary implementations, baseline survey data may be used to initialize the subsurface model prior to executing simulations based on same. In particular, the initialization of the subsurface model may be done following the description above where seismic data and/or well data together with calibrated geo-physics (e.g., rock physics, sand physics, fluid physics data associated with a fluid storage facility) relationship data are used to configure or calibrate the parameters of the subsurface model to indicate flow simulation and estimation of the elastic properties of the subsurface model based on the simulations. Based on the flow simulation a survey may be designed (e.g., via subsequent simulations) to detect changes in the subsurface properties or parameters of the subsurface model during the simulations. During the simulation associated with the survey, one or more parameters of the subsurface model may be adapted based on fluid injection rate data and/or fluid pressure data associated with storing fluid in the subsurface to predict the seismic response by one or more of:
(i) applying saturation data, and/or pressure data, and/or temperature data to vary one or more parameters of the subsurface model;
(ii) estimating effective stress changes associated with geomechanics interactions of one or more parameters of the model;
(iii) estimating the fluid (e.g., gas) compressibility of the subsurface model using an equation of state (EOS) data and/or a National Institute of Standards and Technology NIST dataset (e.g., compliance data);
(iv) applying calibrated rock physics indicated by one or more parameters of the subsurface model to predict an elastic response of the subsurface given the simulated fluid (e.g., CO₂) saturation pressure data, fluid stress data, and temperature data of the subsurface model in space relative to the flow simulation;
(v) varying one or more seismic modeling tests included in the simulation including varying convolutional amplitude-variation-with-angle (AVA) modeling operations using one or more of Zoeppritz techniques, ray tracing operations, and finite difference elastic operations to predict the seismic response given different geometries in the subsurface.

According to one embodiment, spatial and/or temporal fluid distribution data (e.g., fluid pressure data, fluid temperature data, fluid saturation data, etc.) may be generated in response to executing the simulation using the subsurface model. In addition, elastic properties of the subsurface model including seismic wave velocity data (e.g., compressional-wave velocity data Vp and shear-wave velocity data Vs) as well as fluid density data, fluid anisotropy data may also be generated in response to executing the simulation for a given time period.

The ability to simulate the seismic response of the subsurface based on flow or subsurface parameters enable:
(i) generating quality assurance data to optimize the fluid storage operations at the resource site based on the seismic response data when seismic predictions are in conformance with the simulations;
(ii) flagging fluid irregularities which to trigger:
   a. updating flow simulation parameters of the subsurface model based on new spatial and/or temporal patterns by back-projection of the location data of the fluid plume
   b. developing optimal survey design and modeling operations or workflows where source and receiver configuration is selected to best mitigate against potential issues which were not considered before the observations of said deviations.

Benefits from executing the one or more tests or simulations on the model include:
(i) reducing cost in monitoring program for the subsurface fluid storage facility for which the subsurface was developed over the life of the resource site;
(ii) directly and/or dynamically updating parameters associated with the subsurface model based on the simulation;
(iii) commissioning additional geophysics survey where mitigation operations are needed for the subsurface storage facility without incurring additional costs; and
(iv) providing a better handle over volumetric and performance data of the fluid or carbon capture and storage site for future decisions, economic or otherwise, associated with the fluid storage site.

While any discussion of or citation to related art in this disclosure may or may not include some prior art references, Applicant neither concedes nor acquiesces to the position that any given reference is prior art or analogous prior art.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to explain the principles of the invention and its practical applications, to thereby enable others skilled in the art to use the invention and various embodiments with various modifications as are suited to the particular use contemplated. It is appreciated that the term optimize/optimal and its variants (e.g., efficient or optimally) may simply indicate improving, rather than the ultimate form of ‘perfection’ or the like.

It will also be understood that, although the terms first, second, etc., may be used herein to describe various elements, these elements should not be limited by these terms. These terms are used to distinguish one element from another. For example, a first object or step could be termed a second object or step, and, similarly, a second object or step could be termed a first object or step, without departing from the scope of the invention. The first object or step, and the second object or step, are both objects or steps, respectively, but they are not to be considered the same object or step.

The terminology used in the description herein is for the purpose of describing particular embodiments and is not intended to be limiting. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combination of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context.

Those with skill in the art will appreciate that while some terms in this disclosure may refer to absolutes, e.g., all source receiver traces, each of a plurality of objects, etc., the methods and techniques disclosed herein may also be performed on fewer than all of a given thing, e.g., performed on one or more components and/or performed on one or more source receiver traces. Accordingly, in instances in the disclosure where an absolute is used, the disclosure may also be interpreted to be referring to a subset.

What is claimed is:

1. A method for adaptively monitoring a subsurface fluid storage facility, the method comprising:
receiving a first data set associated with a fluid storage site including the subsurface fluid storage facility;
generating a subsurface model for the fluid storage site based on the first data set, wherein the subsurface model comprises a plurality of parameters;
executing at least one simulation using the subsurface model based on fluid data associated with storing fluid in the fluid storage site;
generating predicted fluid distribution data based on the executed simulation, wherein the predicted fluid distribution data comprises fluid pressure data, CO₂ saturation data, spatial fluid data, or temporal fluid data;
receiving a second data set associated with the fluid storage site, wherein the second data set is optimized based on the predicted fluid distribution data;
determining the second data set exceeds a risk threshold;
adapting at least one of the parameters of the subsurface model and re-executing the at least one simulation to provide updated predicted fluid distribution data in response to the second data set exceeding the risk threshold; and
performing an action based in response to re-executing the at least one simulation.

2. The method of claim 1, wherein performing the action in response to re-executing the at least one simulation comprises receiving a third data set associated with the fluid storage site, wherein the third data set is optimized based on the updated predicted fluid distribution data.

3. The method of claim 1, further comprising:
determining the second data set is within the risk threshold;
receiving a third data set associated with the fluid storage site in response to the second data set being within the risk threshold, wherein the third data set is received a predetermined amount of time after receiving the second data set; and
determining whether the third data set in within the risk threshold.

4. The method of claim 1, wherein performing the action comprises:
generating quality assurance data to optimize fluid storage operations at the resource site based on the fluid distribution data; or
indicating fluid irregularities based on the distribution data.

5. The method of claim 1, wherein the received first data set comprises geo-physics data associated with the fluid storage site, and wherein the plurality of parameters of the subsurface model comprises at least one parameter that is based on the geo-physics data associated with the fluid storage site.

6. The method of claim 1, wherein the received first data set comprises risk profile data, and wherein the method further comprises determining the risk threshold from the risk profile data.

7. The method of claim 1, wherein executing at least one simulation comprises executing a plurality of simulations across a corresponding plurality of simulators in parallel.

8. The method of claim 1, wherein performing the action based on the generated distribution data further comprises generating a gas detection map illustrating gas distribution data associated with the fluid storage site.

9. The method of claim 1, wherein performing the action based on the generated fluid distribution data further comprises configuring a plurality of sensors disposed within the subsurface fluid storage facility.

10. The method of claim 1, wherein receiving the first data set associated with a fluid storage site comprises:
receiving the first data set from at least one sensor disposed within the fluid storage site, or
receiving the first data set from an offsite database communicated to the subsurface fluid storage facility.

11. A computing system, comprising:
one or more processors;
a plurality of sensors disposed within a subsurface fluid storage facility and communicated with the one or more processors; and
a memory system comprising one or more non-transitory computer-readable media storing instructions that, when executed by at least one of the one or more processors, cause the computing system to perform operations, the operations comprising:
receiving a first data set associated with a fluid storage site including the subsurface fluid storage facility;
generating a subsurface model for the fluid storage site based on the first data set, wherein the subsurface model comprises a plurality of parameters;
executing at least one simulation using the subsurface model based on fluid data associated with storing fluid in the fluid storage site;
generating predicted fluid distribution data based on the executed simulation, wherein the predicted fluid distribution data comprises fluid pressure data, CO₂ saturation data, spatial fluid data, or temporal fluid data;
receiving a second data set associated with the fluid storage site, wherein the second data set is optimized based on the predicted fluid distribution data;
determining the second data set exceeds a risk threshold;
adapting at least one of the parameters of the subsurface model and re-executing the at least one simulation to provide updated predicted fluid distribution data in response to the second data set exceeding the risk threshold; and
performing an action based in response to re-executing the at least one simulation.

12. The computing system of claim 11, wherein the risk threshold comprises at least one of the following:
a minimum permitted amount of fluid leakage at the fluid storage site;
resolution data of one or more of the plurality of sensors disposed at the fluid storage site; or
regulatory data comprised in the first data set, wherein the regulatory data is based on emission constraints imposed by a regulatory body.

13. The computing system of claim 12, wherein the minimum permitted amount of fluid leakage at the fluid storage site comprises a specific amount of fluid permitted to leak from a primary aquifer into a secondary aquifer, a specific amount of fluid permitted to leak into a legacy well within the subsurface fluid storage facility, or a specific amount of fluid permitted to leak from a first well into a second well.

14. The computing system of claim 11, wherein the plurality of parameters of the subsurface model comprises at least one of the following:
raw data or processed data captured at the fluid storage site;
onshore or offshore geological data associated with the fluid storage site, wherein the geological data comprises seismic data and the temporal or spatial distribution data of subsurface geological structures of the fluid storage site;
well characteristics data comprising well log data, structural data derived from onshore or offshore geological data, faults data, and interpreted geo-layering data;
geophysical data indicating one or more of seismic information, gravity information, electromagnetic information, or nuclear information associated with the fluid storage site; or
configuration data associated with the one or more of the plurality of sensors disposed at the fluid storage site.

15. The computing system of claim 11, wherein executing at least one simulation comprises executing a plurality of simulations across a corresponding plurality of simulators in parallel, wherein the plurality of simulators comprise at least one of the following:
a flow-based simulator based on pressure measurements received from the subsurface fluid storage facility;
an electromagnetic simulator based on formation resistivity data received from the subsurface fluid storage facility;
a nuclear simulator configured to predict responses of a nuclear measurement received from the subsurface fluid storage facility;
a geomechanical simulator configured to predict subsurface responses to changes in mechanical conditions at the fluid storage site;
an electric simulator configured to predict direct or alternating current responses to changes in subsurface conditions at the fluid storage resource site; or
an acoustic simulator based on acoustic properties received from the subsurface fluid storage facility.

16. The computing system of claim 11, wherein performing the action based on the fluid distribution data comprises generating a report comprising at least one of the following:
a fluid detection map illustrating gas distribution data associated with the fluid storage site;
a matrix indicating efficacy level data for using a plurality of different gas storage operations at the fluid storage site based on the at least one executed simulation;
a plurality of tabular data comprising the fluid distribution data;
a two-dimensional illustration indicating a first monitoring design for optimally monitoring fluid stored at the fluid storage site; or
a three-dimensional illustration indicating a second monitoring design for optimally monitoring fluid stored at the fluid storage site.

17. The computing system of claim 11, wherein executing the at least one simulation plan comprises executing a plurality of simulation streams, wherein each simulation stream is performed by a corresponding gas storage sub-model associated with the fluid storage site.

18. The computing system of claim 17, wherein the gas storage sub-model corresponding to each simulation stream comprises at least one of the following:
fault characteristics data associated with the fluid storage site;
transmissibility data associated with the fluid storage site; or
distribution data indicating statistical characterizations of the subsurface of the fluid storage site.

19. The computing system of claim 11, wherein the plurality of sensors are distributed acoustic sensors.

20. A non-transitory computer-readable medium storing instructions that, when executed by one or more processors of a computing system, cause the computing system to perform operations, the operations comprising:
receiving a first data set associated with a fluid storage site, wherein the first data set comprises geo-physics data associated with the fluid storage site and risk profile data, wherein the first data set is received from at least one sensor disposed within the fluid storage site or from an offsite database communicated to the fluid storage site;
generating a subsurface model for the fluid storage site based on the first data set, wherein the subsurface model comprises a plurality of parameters, wherein the plurality of parameters of the subsurface model comprises at least one parameter that is based on the geo-physics data associated with the fluid storage site;
executing a plurality of simulations using the subsurface model based on fluid data associated with storing fluid in the fluid storage site, wherein the plurality of simulations are executed across a corresponding plurality of simulators in parallel for a plurality of different predefined time periods;
generating predicted fluid distribution data based on the executed simulation, wherein the fluid distribution data comprises fluid pressure data, CO₂ saturation data, spatial fluid data, or temporal fluid data;
receiving a second data set associated with the fluid storage site, wherein the second data set is optimized based on the predicted fluid distribution data;
determining the second data set exceeds a risk threshold, wherein the risk threshold is based on the risk profile data;
adapting at least one of the parameters of the subsurface model and re-executing the at least one simulation to provide updated predicted fluid distribution data in response to the second data set exceeding the risk threshold; and
performing an action based in response to re-executing the at least one simulation, wherein performing the action comprises:
generating quality assurance data to optimize fluid storage operations at the resource site based on the fluid distribution data;
generating a gas detection map illustrating gas distribution data associated with the fluid storage site;
configuring a plurality of sensors disposed within the subsurface fluid storage facility; and
indicating fluid irregularities based on the distribution data, wherein indicating fluid irregularities based on the distribution data comprises updating flow simulation parameters comprised in the plurality of parameters of the subsurface model, or developing an optimal survey design and modeling workflow for the subsurface fluid storage facility.
